(19) United States
(12) Patent Application Publication
(10) Pub. No.: US 2010/0259259 A1
(43) Pub. Date: Oct. 14, 2010

(54) Systems and methods for tuning properties of nanoparticles

(76) Inventors: Markus Zahn, Lexington, MA (US); Elfar Adalsteinsson, Belmont, MA (US)

Correspondence Address: WEINGARTEN, SCHURGIN, GAGNEBIN & LEBOVICI LLP, TEN POST OFFICE SQUARE, BOSTON, MA, 02109, US

(21) Appl. No.: 11/525,234

(22) Filed: Sep. 21, 2006

Related U.S. Application Data
(60) Provisional application No. 60/719,681, filed on Sep. 21, 2005.

(51) Int. Cl. G01R 33/48; G01R 33/44

(52) U.S. Cl. 324/309; 324/318

(57) ABSTRACT

Systems and methods for imaging include preparing a ferrofluid including magnetic nanoparticles (MNPs) in a liquid carrier, positioning the ferrofluid in a field region of a magnetic resonance imaging (MRI) system, and actuating a spin velocity or linear velocity of the magnetic nanoparticles to alter the scalar or tensor complex magnetic susceptibility (CMS) of the ferrofluid. Additional activation magnetic field generating apparatus can tune the magnetic field to change particle spin velocity or linear velocity. The method provides, inter alia, for using the spinning MNPs to: heat or cool a region of interest; acquire an improved image of the nanoparticles within a region of interest; alter local effective viscosity, diffusion coefficient, magnetic field, and/or other electromagnetic and/or physicochemical properties; cause local mixing; and enhance diffusion in drug delivery. Parallel methods with dielectric nanoparticles and electric fields are also disclosed.

### CROSS REFERENCE TO RELATED APPLICATIONS

This application claims the benefit of U.S. provisional patent application No. 60/719,681 filed on Sep. 21, 2005, which is incorporated herein in its entirety by reference.

### BACKGROUND

Magnetic nanoparticle suspensions (ferrofluids) are synthesized colloidal mixtures of a non-magnetic carrier liquid, typically water or oil, containing single domain permanently magnetized particles, typically magnetite, with diameters of order 5-15 nm and volume concentrations of up to about 10%.

When a magnetic field is applied to a ferrofluid, each magnetic nanoparticle can experience a torque, which tends to align the particle magnetic moment with the field, and/or a force in the direction of strong magnetic field. The response of such particles to magnetic and/or electric fields induced by fluid and/or nanoparticle motion, to externally induced magnetic and/or electric fields, fluid flow, fluid vorticity, fluid spin velocity, temperature, and other disturbances can cause changes in the ferrofluid's electromagnetic and physical properties, such as effective magnetoviscosity, compressibility, magnetic moment magnitude and direction, complex magnetic susceptibility and magnetic field outside the ferrofluid volume. Similar effects result for an electric field applied to dielectric fluid suspensions of lossy or lossless dielectric nanoparticles. Magnetic nanoparticles may also be lossy dielectric nanoparticles

Industrial applications of ferrofluids are extensive and diverse. For instance, ferrofluids are used for heat transfer in audio speakers, as rotary seals for contaminant exclusion in computer disk drives, and for damping vibrations in helicopter rotor assemblies.

Brownian motion typically keeps nanoparticles from settling under gravity and often a polymeric layer or surfactant, such as oleic acid, surrounds each particle in order to provide short range steric hindrance and electrostatic repulsion between particles, thus preventing particle agglomeration.

Many researchers are using ferrofluids for biomedical procedures. The dispersant coating of the magnetic nanoparticles can also be designed to have additional specific attributes for diagnostic or therapeutic applications, such as selectively binding to drugs, molecular groups, proteins, cells, and organisms. Other uses have been related to heating for therapeutic purposes.

Magnetic resonance imaging (MRI) is based on transient signals of protons from water in tissues using a strong DC magnetic field, B₀, typically 1.5 T, and a transverse RF excitation field (typically about 0.1 Gauss for 1-5 ms at 65 MHz). Tissues can be differentiated by their different T₁ and T₂ relaxation times. Image contrast is adjusted, for example, by changing the repetition time, TR, between successive RF pulses, or the echo time delay, TE, between the RF pulse and measurement of the magnetization signal. Increasing the strength of B₀ fields and RF excitation fields in order to increase signal-to-noise ratio brings with it concerns for human safety and higher cost.

There continues to be a need for further improvements in MRI contrast imaging for human and other mammals, cadavers, plants, any living organisms, inanimate objects, and/or any other application of MRI, particularly at existing and lower intensities of the B₀ field, as well as for other combined research, diagnostic and/or therapeutic interventions in association with MRI imaging.

### SUMMARY

A preferred embodiment of the present invention provides for systems and methods of magnetic resonance imaging (MRI) that includes preparing a ferrofluid of magnetic nanoparticles (MNPs) in a liquid carrier, positioning the ferrofluid in a field region of a magnetic resonance imaging (MRI) system, and actuating a spin of the magnetic nanoparticles to alter a valve of the complex magnetic susceptibility (CMS) of the ferrofluid. The method can provide for using these spinning MNPs to cause diagnostic or therapeutic benefits for a patient, such as to heat or cool a region of interest, to acquire a relatively improved image in the vicinity of the nanoparticles within the region of interest (MRI contrast enhancement), to alter local effective viscosity, diffusion coefficient, magnetic field due to changes in valves of the CMS, and/or other physicochemical properties, and/or to cause local mixing for cooling or heating, enhanced diffusion in drug delivery and other purposes.

The imaginary components of the complex magnetic susceptibility valves can be represented by vector or tensor representations having a plurality of components. The present invention relates to a system for selectively controlling the valves (direction and magnitude) of these components for treatment and imaging of a region of interest.

A preferred embodiment provides for tuning of MNP properties, including actuating spin in MNPs to alter the CMS of a ferrofluid by a flow with vorticity and/or together with imposing suitable additional magnetic field(s) (oriented in various directions), such as direct current (DC) magnetic fields, oscillating magnetic fields, rotating magnetic fields and/or traveling magnetic fields, and tuning or modulating one or more of these magnetic fields and/or the flow of the ferrofluid using a variety of waveforms, including pulse and sinusoidal amplitude waveforms, amplitude modulation, frequency modulation, and/or phase modulation, inter alia. A further embodiment includes additionally modulating such field(s) and/or flow for biomedical applications, including in conjunction with MRI, pre-polarized MRI (pMRI) and/or functional MRI (FMRI) applications to cause diagnostic or therapeutic benefits such as those listed above.

Another preferred embodiment of the invention further provides for actuating spin in dielectric nanoparticles (DNPs) to alter the complex dielectric susceptibility (CDS) of a dielectric fluid suspension (DFS) by a flow with vorticity and/or together with generating suitable, additional electric field(s) oriented in various directions, such as DC electric fields, oscillating electric fields, rotating electric fields and/or traveling electric fields, inter alia. By modulating one or more of these fields and/or the flow of the DFS using a variety of waveforms, including pulse and sinusoidal amplitude waveforms, amplitude modulation, frequency modulation and/or phase modulation, inter alia will cause MNPs and/or DNPs to further move translationally and/or rotationally. A further embodiment provides for applying such modulation in conjunction with biomedical applications, including MRI, pMRI and/or fMRI applications to cause diagnostic or therapeutic actions, such as those listed previously, and/or to cause electrokinetic, electromotive or electrosensory actions, inter alia.

Another preferred embodiment provides for generating one or more of a DC magnetic and/or electric field, an oscillating magnetic and/or electric field, a rotating magnetic and/or electric field, or a traveling magnetic and/or electric field, inter alia, and generating a fluid flow in a portion of a ferrofluid and/or a dielectric fluid suspension (DFS) and modulating the fields and/or fluid flow to cause MNPs in the ferrofluid and/or DNPs in the DFS to spin, thereby altering the CMS of the ferrofluid and/or the CDS of the DFS. Additionally, translational movement of the MNPs and/or DNPs can be performed with an external DC, oscillating, rotating, or traveling magnetic or electric field, inter alia.

A magnetic field can be rotated, for example, altering its amplitude, frequency, phase and/or direction in order to alter a spin velocity and/or linear velocity of the ferrofluid. The procedure can include altering the CMS of a ferrofluid and forming a magnetic resonance (MR) image, temporally modulating the effective CMS of the ferrofluid to cause temporal modulation of signal intensity (i.e., intermittent fluctuations in image contrast) in the MR image, identifying an attachment location of the MNPs, using the MNPs as an MRI contrast agent, preparing the MNPs with a surfactant or surface coating, and/or using the surfactant to colloidally stabilize the MNPs.

A magnetic resonance imaging (MRI) system in accordance with the invention can include a magnetic field generating system providing a generally DC magnetic field within a spatial region in which material to be imaged is located, an RF electromagnetic radiation generating and receiving system that generates magnetic resonance data in response to magnetic resonance within the material, a gradient magnetic field for spatial encoding, a control system that controls a plurality of pulse parameters, and an image processor for receiving the collected MR data. An additional activation magnetic field generating system can be used that generates a varying magnetic field, and a ferrofluid including magnetic nanoparticles that spin in response to the activation magnetic field, the activation magnetic field inducing a change in the CMS of the ferrofluid which causes changes in the magnetic field external to the MNPs.

An electronic spin resonance (ESR) system in accordance with the invention can include a magnetic field generating system providing a magnetic field within a spatial region in which material to be imaged or detected is located, an additional oscillating magnetic field superimposed on the detection region, an electromagnetic radiation generating system (for example, an alternating microwave radiation from a Klystron tube including heated cathode, collecting anode and reflector electrode), a power-level adjustment attenuator, a diode detector with coupled ammeter, wherein the tube generates microwave electronic resonance energy and the diode detector receives the ESR response from the material, wherein further there is provided an activation electric field generating system that can generate a varying electric field and a DFS including DNPs that spin in response to the activation electric field, the activation electric field inducing a change in the complex dielectric susceptibility of the dielectric fluid suspension.

Another preferred embodiment for magnetic resonance imaging of magnetic nanoparticles can be enhanced by localization, targeting and delivery of these particles for hyperthermia and other therapeutic purposes, such as mixing, heating, cooling and changing of local effective viscosity, diffusion coefficient, magnetic field due to changes in scalar or tensor CMS, or other electromagnetic and/or physicochemical properties, inter alia.

A preferred embodiment of an integrated imaging and thermotherapy system combines in vivo MR imaging of targeted magnetic nanoparticle delivery and monitoring of remotely induced hyperthermia from an applied rotating magnetic field. A preferred system according to the invention comprises an MRI scanner for imaging of injected nanoparticles as an improved contrast agent in combination with an external magnetic field to steer the particles to a desired location (identified by imaging) followed by magnetically induced hyperthermia (monitored by imaging).

Additionally, a preferred embodiment includes a method for: (i) magnetically tuning and controlling the heating rate by using an alternating, oscillating or rotating magnetic field to cause magnetic nanoparticle spin to change the imaginary part of the complex magnetic susceptibility of the ferrofluid which governs the heating rate, (ii) modulating the MRI T1 and T2 time constants by, and/or in the presence of, spinning magnetic nanoparticles to introduce an independent, external control of local MR contrast for imaging, and/or (iii) mixing, heating, cooling and changing of local effective viscosity, diffusion coefficient, magnetic field due to changes in scalar or tensor CMS, or other electromagnetic and/or physicochemical properties, inter alia.

A preferred embodiment of the invention can provide for a magnetic field amplitude, frequency, phase and direction control of biomedical procedures for such applications as, inter alia:

(i) identification of ferrofluid position and binding location by intermittent fluctuations in image contrast in an MRI with periodic turning on and off of a magnetic field (i.e., causing temporal modulation of the localized MRI signal intensity); (ii) causing viscous and crystalline heating by controlled magnetic particle and magnetization rotation through Brownian and Néel relaxation; (iii) enhancing diffusion in magnetic nanoparticle absorption/desorption processes (e.g., directed drug delivery) by controlled local mixing by spinning magnetic nanoparticles; (iv) accurate control of delivery of thermotherapy; (v) real-time in vivo monitoring of the effects of thermotherapy; (vi) changing of local effective viscosity, diffusion coefficient, magnetic field due to changes in scalar or tensor CMS, or other electromagnetic and/or or other physicochemical properties, and (vii) cutting, scraping, abrading or removing biological material such as tissue, plaque, gall stones, kidney stones, and/or opening blocked vessel channels such as veins, arteries, urethra, etc., inter alia.

A preferred embodiment can provide for controlling the ferrofluid magnetic nanoparticle spin velocity by external control of magnetic field amplitude, frequency, phase and direction or by the flow profile which is also magnetic field controllable through the magnetic forces and torques on the ferrofluid.

A further embodiment of the invention provides for modulation of the applied rotating magnetic field to change the ferrofluid scalar or tensor CMS and thereby temporally modulate MRI signal intensity (i.e., causing intermittent fluctuations in image contrast, or an enhancement effect) so that the location of the magnetic nanoparticles can be more easily detected. If the nanoparticle has a functionalized surface coating selectively adsorbing to specific media, such as a tumor, then the MNP provides an effective cancer therapy. The intermittent fluctuations in image contrast in the MRI identifies the location of the tumor, which can then be treated with the help of magnetic nanoparticle heating. The invention also provides for in vivo imaging of targeted delivery and monitoring of remotely induced hyperthermia as a cancer therapy. Other uses include enhancing drug efficacy or mediating drug delivery through magnetic or electric field manipulation of MNPs or DNPs, and/or changing of local effective viscosity, diffusion coefficient or other physicochemical properties.

A preferred embodiment of the invention provides for controlling particle position, linear and spin velocities, and heating with the magnetic properties of the magnetic nanoparticles and external magnetic field control. The small particle size enables passage through organ and tissue capillary systems without threat of vesicle embolism and, with a functionalized coating, the particles can transport therapeutic agents. An external DC or alternating magnetic field steers and/or holds the magnetic nanoparticles (MNPs) at desired locations, while rotating and traveling magnetic fields cause linear and rotating motion to, for instance, free nanoparticles if locally trapped, create local mixing to enhance diffusion processes, heat or cool the particles and their adjacent environment; cutting, scraping, abrading or removing biological material such as tissue, plaque, gall stones, kidney stones, and/or opening blocked vessel channels such as veins, arteries, urethra, etc., inter alia. MNPs can be spherical or non-spherical shaped, such as needle-shaped, with knife-edged sharp edges or smooth edges to facilitate therapeutic applications.

The invention can provide for using MNPs simultaneously with magnetic field tuning of MRI contrast quality and heating.

A preferred embodiment provides for functionalization of nanoparticles with magnetic and surface properties (such as incorporating a surfactant, or surface coating, that functionalizes the particle for therapeutic effect), tailored for application as micro/nanoelectromechanical sensors, actuators, in micro/nanofluidic devices, as nanobiosensors, as targeted drug-delivery vectors, in magnetocytolysis of cancerous tumors, in hyperthermia, in separations and cell sorting, as contrast agent for magnetic resonance imaging (MRI), and in immunoassays, where said nanoparticles are controlled in terms of spin velocity by a magnetic and/or electric field and/or flow with vorticity so as to alter the CMS of the nanoparticles.

### BRIEF DESCRIPTION OF THE DRAWINGS

FIG. 1 illustrates a preferred embodiment of a magnetic field tunable MRI system in accordance with the present invention.

FIGS. 2A-2D generally show representations of longitudinal relaxation in a magnetic resonance imaging system, also known as spin lattice relaxation or T1 recovery, which is the time for the proton magnetization to align with B₀ after radio frequency (RF) excitation, and transverse relaxation, also known as spin-spin relaxation or T2 decay, which is the time for transverse magnetization to decay after the RF pulse is removed. FIG. 2A depicts Larmor Precession of Photons; FIG. 2B depicts Transverse Magnetization; FIG. 2C shows Transverse Relaxation; and FIG. 2D shows Longitudinal Relaxation.

FIG. 3 is a schematic depiction of a spherical magnetic nanoparticle in a colloidal dispersion, or ferrofluid.

FIG. 4A is a schematic depiction of a one-pole pair stator winding for generating a uniform rotating magnetic field.

FIG. 4B illustrates uniform magnetic field lines shown by iron powder patterns in a one-pole pair stator.

FIG. 5A is a schematic depiction of a two-pole pair stator winding that generates a non-uniform rotating magnetic field.

FIG. 5B illustrates non-uniform magnetic field lines shown by iron powder patterns for a two-pole pair stator.

FIG. 5C shows the equilibrium Langevin magnetization for various particle radii as a function of α=μ₀ mH/kT.

FIG. 6 illustrates, for combined planar Couette and Poiseuille flow Vₓ(y), fluid spin velocity ω_{z} and magnetic field components H_{z} (out of page), Hₓ in the x-direction of the flow, and H_{y} in the y-direction.

FIG. 7 shows the normalized imaginary part of the complex magnetic susceptibility (CMS) χₓₓᵢ,/χ₀, as a function of non-dimensional frequency Ωτ for various values of non-dimensional spin velocity ω_{z}τ.

FIGS. 8A-8F and 9A-9F are images of ferrofluid drops in a glass thin-layer (Hele-Shaw) cell that has simultaneously applied horizontally rotating and vertical DC magnetic fields.

FIG. 10 is a schematic depiction of a boundary between a magnetic fluid and a non-magnetic fluid in a thin-layer (Hele-Shaw) cell for demonstrating exposure to a magnetic field.

FIGS. 11A-11J illustrate magnetic and dielectric fluid mixing across a boundary, as follows: FIGS. 11A-11D illustrate progressive stages of a magnetic fluid mixing across a boundary into a non-magnetic fluid; FIGS. 11E-11G illustrate three labyrinthine mixing patterns of a magnetic fluid at differing magnetic field strengths and gaps; and FIGS. 11H-11J illustrate three labyrinthine mixing patterns of a dielectric fluid at differing electric field strengths and gaps.

FIGS. 12A-12D are images of vials in an MRI phantom constructed to demonstrate the effect of differing magnetic fluid concentrations on MRI time constants T1 and T2.

FIG. 13A is a measured graph of decreasing T2 signal intensity with increasing echo time delay, TE, for differing dilutions of a ferrofluid, where repetition time is held constant, TR=5 s.

FIG. 13B is a plot of the theoretical contribution to T2 due to MNPs of magnetite for various particle radii with a particle volume concentration of 1.375×10⁻⁶.

FIG. 14A is a measured graph of increasing T1 signal intensity with increasing repetition time, TR, for differing dilutions of a ferrofluid, where echo time delay is held constant, TE=14 ms.

FIG. 14B is a plot of the theoretical contribution to T1 due to MNPs of magnetite for various particle radii with a particle volume concentration of 1.375×10⁻⁶.

FIGS. 15A and 15B illustrate how the imaginary part of the complex magnetic susceptibility (CMS) leads to power dissipation (positive) or pumping (negative). Non-dimensional power dissipation is shown as a function of non-dimensional frequency for various non-dimensional spin velocities. FIG. 15A is for an applied uniform oscillating field, while FIG. 15B is for an applied uniform rotating field.

FIG. 16A is another measured image of vials with concentrations given in Table 2 to demonstrate the effect of differing magnetic fluid concentrations on MRI contrast by increasing the time constants T1 and T2.

FIG. 16B shows a comparison of the theoretical prediction of T2 from Eqs. 15-17 for various particle radii with the experimental results over a range of FERROTEC® MSG W11™ ferrofluid concentrations of an original 2.75% solution by volume.

FIGS. 17A and 17B illustrate how the inductance and resistance of FERROTEC® MSG W11™ ferrofluid are changed by activation of rotating magnetic fields according to preferred embodiments of the invention: FIG. 17A shows measured inductance L′=Re[L] [H] as a function of frequency; FIG. 17B is the measured total resistance R_{w}+ΩL″=R_{w}+ΩIm[L] [Ohm] as a function of frequency.

FIGS. 18A and 18B illustrate how the inductance and resistance of FERROTEC® MSG W11™ ferrofluid are changed by activation of rotating and DC magnetic fields according to preferred embodiments of the invention: FIG. 18A shows the real part of the inductance, L′[Henries] as a function of frequency; FIG. 18B shows the resistance R_{w}+ΩL″ as a function of frequency.

FIG. 19A shows an example of a timing sequence of a preferred method of employing an activation magnetic field with an MRI system, wherein Bᵣₒₜ is an activation rotating magnetic field applied to induce particle spin velocity and A/D indicates a sequence of data acquisition, in which analog data is collected and converted to digital data for processing.

FIG. 19B shows a further example of a timing sequence of an embodiment of the invention providing a method for interleaving time intervals of preparation and imaging.

FIG. 19C shows a further example of a timing sequence of an embodiment of the invention providing a method for interleaving time intervals of one or more interventions and imaging.

FIG. 20 shows an example of a coil configuration for a two-flux-sphere activation apparatus according to an embodiment of the invention.

### DETAILED DESCRIPTION

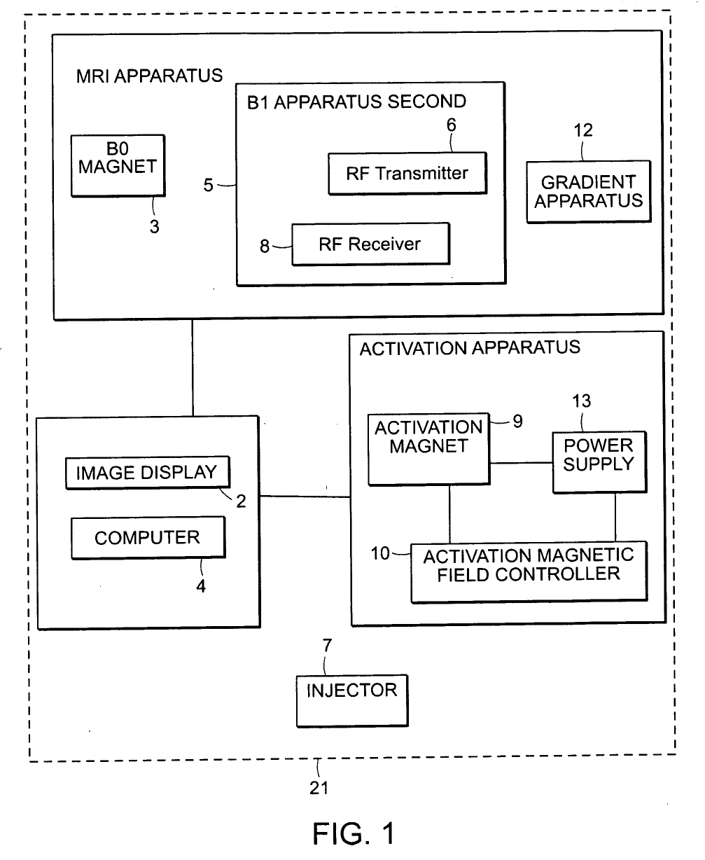

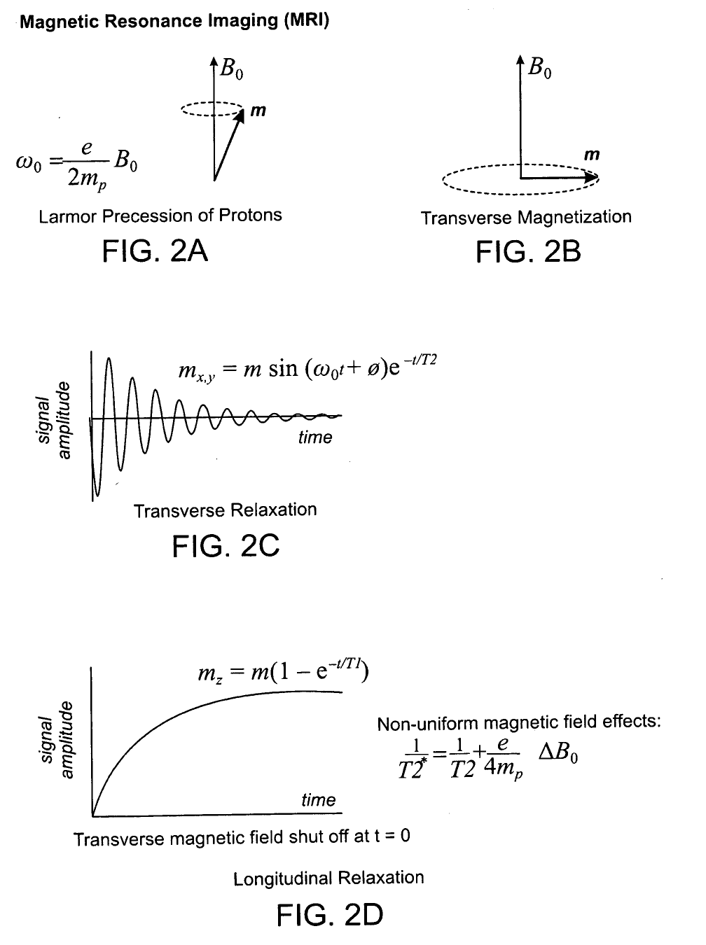

Preferred embodiments of the invention generally relate to magnetic field tuning of magnetic nanoparticle properties for biomedical applications. As shown in FIG. 1, a preferred embodiment of the present invention provides for magnetic field tuning in a magnetic resonance imaging (MRI) system, wherein images are generated in relation to T1 and T2 relaxation times, as depicted in FIGS. 2A-2D. The procedure includes preparing a ferrofluid comprising magnetic nanoparticles (MNPs) in a liquid carrier, positioning the ferrofluid in a field region of the magnetic resonance imaging (MRI) system, and employing an activation magnetic field to actuate a spin of the magnetic nanoparticles to alter the complex magnetic susceptibility (CMS) of the ferrofluid. The ferrofluids thus altered can be manipulated at a distance with a variety of combinations of DC, AC, traveling and rotating magnetic fields and can serve as enhanced contrast agents for MR imaging, enhanced mediators for magnetic hyperthermia and/or hypothermia (induced local heating or cooling, respectively), and magnetokinetic agents for other diagnostic and therapeutic applications.

A preferred embodiment of the invention utilizes a ferrofluid that is a synthesized colloidal mixture comprising single-domain, permanently magnetized nanoparticles, composed of magnetite in the core, with diameters (twice the hydrodynamic radius, Rₕ) preferably on the order of 5-15 nm, suspended in a non-magnetic carrier liquid, typically water or oil, at volume concentrations of up to about 10%. The preferred range of diameter is to optimize colloidal stability, although other diameter particles can be used in accordance with the invention. Further embodiments of the invention do not require a stable colloidal suspension, and therefore do not require a stabilizing surfactant although surfactants may still be used for other functions. The MNPs and/or dielectric particles can be any shaped particles, such as spherical, non-spherical, or needle-shaped with smooth or sharp edges, inter alia, with or without surface coatings or surfactants, or can be encapsulated particles of magnetic, dielectric, and/or conducting materials, inter alia. The encapsulation material could have any useful properties such as being magnetic, dielectric, or conducting, inter alia, can be with or without a surface coating and can, for example, enclose materials that might otherwise be toxic or might have other useful properties for therapeutic purposes, such as slowly dissolving in the body to release the encapsulated materials which might include medication or other beneficial materials.

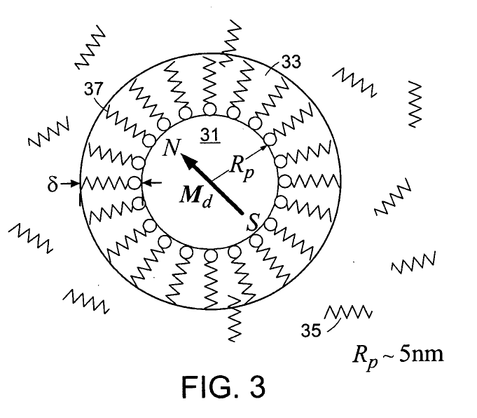

The magnetic nanoparticles comprising the ferrofluid can be prepared by any method such as grinding of larger micron sized particles or by chemical precipitation of magnetic materials, such as chemical reactions of iron from iron-containing molecules. Commercial suppliers of such ferrofluids include Ferrotec Corp. (Nashua, N.H.) and Liquids Research Limited (Bangor, Wales, U.K.). Biocompatible, ferrofluid-containing mixtures for biomedical applications are also available from many sources such as Chemicell Corp. (Berlin, Germany), Invitrogen (Carlsbad, Calif.), and Bangs Laboratories (Fishers, Ind.). For biomedical applications critical specifications are particle size and surfactant, and biocompatibility of carrier fluid. The particles can be coated with a surfactant. FIG. 3 schematically depicts the permanently magnetized core 31, of radius R_{p′}=˜5 nm in this example, surrounded by an adsorbed dispersive surfactant 33, of thickness δ, so that Rₕ=Rₚ+δ, where Rₕ is known as the hydrodynamic radius, with magnetic dipole magnetization, M_{d}, oriented in the direction of the S-N arrow. Solvent molecules 35 surround the surfactant outer boundary 37.

When a DC magnetic field H̅ is applied to a ferrofluid, each magnetic nanoparticle, with magnetic moment m̅= M̅_{d}Vₚ where M̅_{d} is the particle single domain magnetization, equal to 446 kA/m for magnetite and

$${V}_{p} = \frac{4}{3} π {R}_{p}^{3}$$

is the magnetic nanoparticle volume for a spherical particle, experiences a torque, μₒ m̅× H̅, which tends to align m̅ and H̅. There are two important time constants that determine how long it takes m̅ to align with H̅: τ_{B}=3ηVₕ/kT where

$${V}_{h} = \frac{4}{3} π {R}_{h}^{3}$$

is the total nanoparticle volume for a spherical particle; and τₙ=τₒe^{(KV}^{ₚ}^{/kT)}. The Brownian rotational relaxation time, τ_{B}, describes the hydrodynamic process when the magnetic moment is fixed to the nanoparticle and surfactant layer of total hydrodynamic volume Vₕ, (for example, where

$${V}_{h} = \frac{4}{3} π {( {R}_{p} + δ )}^{3}$$

for a spherical particle) and the whole nanoparticle rotates in a fluid of viscosity η to try to align m̅ and H̅. The Néel time constant, τ_{N}, is the characteristic time for the magnetic moment to align with H̅, without particle rotation. The parameter K is the particle magnetic anisotropy and Vₚ=(4/3)πRₚ³ is the volume of magnetic material alone. The total magnetic time constant τ, when both Néel and Brownian relaxation mechanisms are operative, is given by:

1/τ=1/τ_{b}+1/τ_{N} [symbol] τ=(τ_{b}τ_{N})/(τ_{B}+τ_{N}) (Eq. 1)

where the smallest time constant, Brownian or Néel, dominates.

In a rotating magnetic field the magnetization of liquid suspensions of magnetic nanoparticles lags the magnetic field so that the torque on each nanoparticle causes the particles and surrounding fluid to spin. This provides a system in which the fluid behaves as if it is filled with nanosized gyroscopes that stir, mix, and heat the fluid.

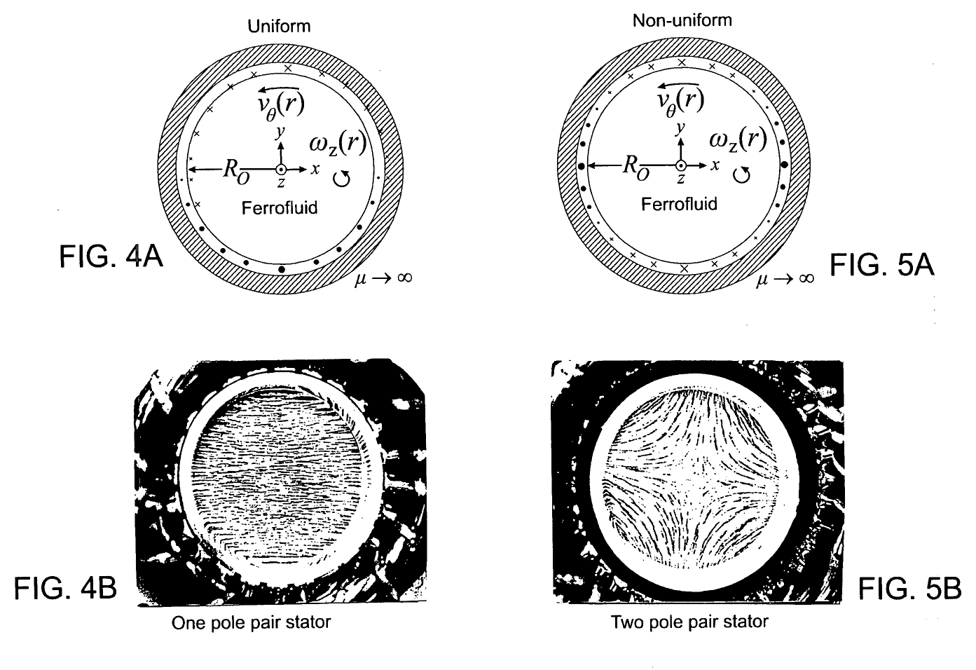

Rotating magnetic fields can be uniform or non-uniform. A uniform, rotating magnetic field in the x-y plane, for example, is generated by a one-pole-pair stator winding as shown in FIG. 4A, with a z-directed surface current that is given by

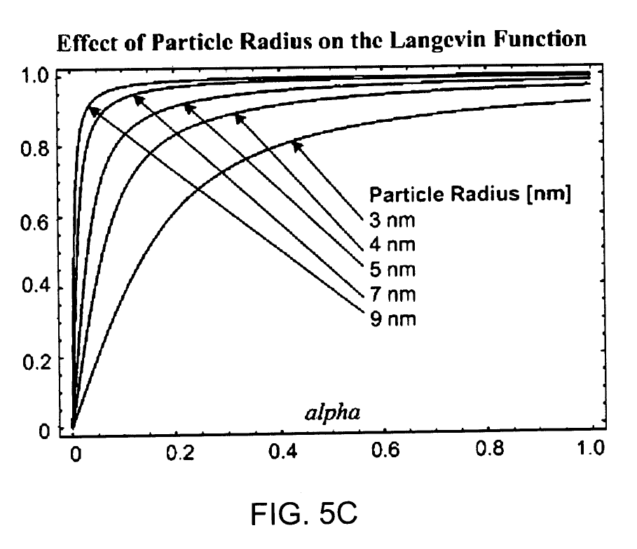

K_{z}=Re{\hat{K}e^{j(Ω1-θ)}} (Eq. 2)

where \hat{K} is the surface current complex amplitude, Ω is the sinusoidal radian frequency, θ is the azimuthal coordinate angle, j=\sqrt{−1} and Re denotes the real part of the complex expression. This uniform rotating magnetic field creates uniformly-spaced magnetic field lines as shown by the iron powder patterns in FIG. 4B. A non-uniform, rotating magnetic field in the x-y plane, for example, is generated by a two-pole-pair stator winding as shown in FIG. 5A, with a z-directed surface current, given by

K_{Z}=Re{\hat{K}e^{j(Ω1-2θ)}} (Eq. 3)

and creates non-uniform magnetic field lines as shown by the iron powder patterns in FIG. 5B.

Ferrofluid equilibrium magnetization M̅₀ of mono-dispersed particles is accurately described by the Langevin equation for paramagnetism:

M₀=Mₛ[cothα−1/α], α=μ₀mH/kT (Eq. 4)

where M̅₀ and H̅ are collinear, Mₛ=Nm=M_{d}φ is the saturation magnetization when all magnetic dipoles with moment m=M_{d}Vₚ are aligned with H, N is the number of magnetic dipoles per unit volume, and φ is the volume fraction of magnetic nanoparticle material in the ferrofluid. At low values of magnetic field, Eq. 4 reduces to M̅₀=χ₀ H̅ where χ₀ is the equilibrium magnetic susceptibility. FIG. 5C shows how the equilibrium magnetization of Eq. 4 varies with parameter α for various nanoparticle radii.

Ferrofluid magnetization generally obeys a relaxation equation such as

$$\frac{\partial \overline{M}}{\partial t} + ( \overline{v} \cdot ∇ ) \overline{M} - \overline{ω} \times \overline{M} + \frac{\overline{M}}{τ} = \frac{{\overline{M}}_{0}}{τ} \qquad ( Eq . 5 )$$

where M̅₀ is the equilibrium magnetization, ν̅ is the fluid flow velocity and ω̅ is the fluid spin velocity.

At small magnetic fields, the equilibrium magnetic susceptibility of a magnetic nanoparticle suspension with spherical particles of diameter d is obtained from the Langevin relationship as

$${χ}_{0} = \frac{{M}_{0}}{H} = \frac{π}{18} \frac{{μ}_{0} φ {M}_{d}^{2} {d}^{3}}{kT} \qquad ( Eq . 6 )$$

where M₀ is the equilibrium magnetization of the material, measured in A/m and H is the applied field, also measured in A/m.

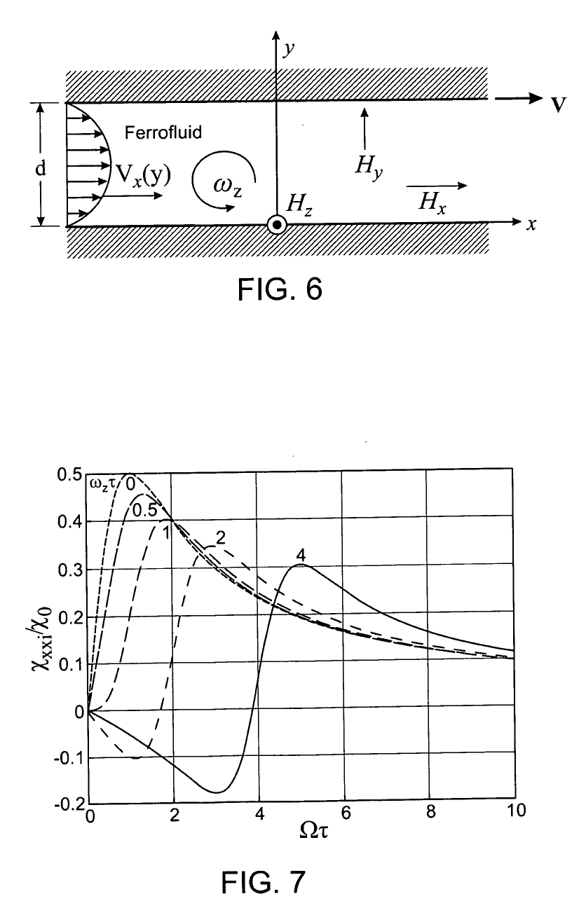

For the two-dimensional, fully developed planar channel flow illustrated in FIG. 6 with V_{X}(y) being a combined planar Couette and Poiseuille flow, ω_{z} and M̅can only depend on y. Then the second term in Eq. 5 is zero. Other flows could have the second term in Eq. 5 be non-zero.

Then, in the sinusoidal steady state at radian frequency Ω, the M̅ and H̅ fields are of the form

M̅=Re[ \overline{\hat{M}}e^{jΩ1}], H̅=Re[ Ĥ̅e^{jΩ1}] (Eq. 7)

where \overline{\hat{M}} and Ĥ̅ are the vector complex amplitudes, j=\sqrt{−1}, and Re denotes the real part of the complex expression. Then assuming that the second term in Eq. 5 is zero, the solution to Eq. 5 is

\overline{\hat{M}}= χ̅· Ĥ̅ (Eq. 8)

where χ̅ is the complex magnetic susceptibility tensor as given by

$${{χ}^{\overline{\_}}}_{m} = \frac{{χ}_{0} [ \begin{matrix}{( j Ωτ + 1 )}^{2} + {( {ω}_{x} τ )}^{2} & {ω}_{x} {ω}_{y} {τ}^{2} - ( j Ωτ + 1 ) {ω}_{z} τ & {ω}_{x} {ω}_{z} {τ}^{2} + ( j Ωτ + 1 ) {ω}_{y} τ \\ {ω}_{x} {ω}_{y} {τ}^{2} + ( j Ωτ + 1 ) {ω}_{z} τ & {( j Ωτ + 1 )}^{2} + {( {ω}_{y} τ )}^{2} & {ω}_{y} {ω}_{z} {τ}^{2} - ( j Ωτ + 1 ) {ω}_{x} τ \\ {ω}_{x} {ω}_{z} {τ}^{2} - ( j Ωτ + 1 ) {ω}_{y} τ & {ω}_{y} {ω}_{z} {τ}^{2} + ( j Ωτ + 1 ) {ω}_{x} τ & {( j Ωτ + 1 )}^{2} + {( {ω}_{z} τ )}^{2}\end{matrix} ]}{( j Ωτ + 1 ) [ {( j Ωτ + 1 )}^{2} + {( {ω}_{x} τ )}^{2} + {( {ω}_{y} τ )}^{2} + {( {ω}_{z} τ )}^{2} ]} \qquad ( Eq . 9 )$$

For example, if Ĥ_{y}=Ĥ_{z}=0, ω̅=ω_{z}ī_{z} then

$${\hat{M}}_{x} = \frac{{χ}_{0} ( j Ωτ + 1 ) {\hat{H}}_{x}}{{( j Ωτ + 1 )}^{2} + {( {ω}_{z} τ )}^{2}} \qquad ( Eq . 10 )$$

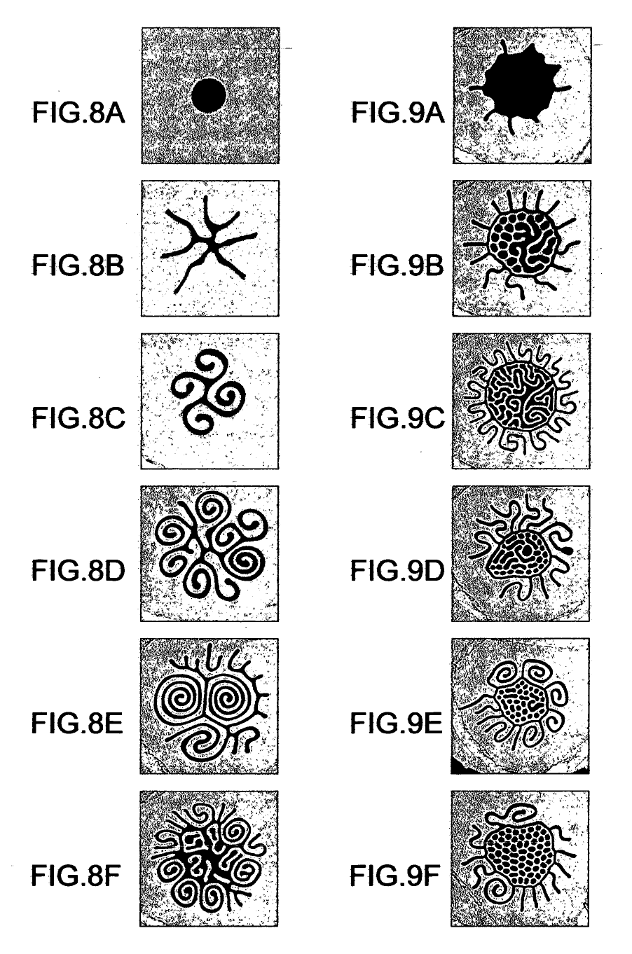

The CMS component used in this embodiment is then

$${χ}_{xx} = \frac{{\hat{M}}_{x}}{{\hat{H}}_{x}} = \frac{{χ}_{0} ( j Ωτ + 1 )}{{( j Ωτ + 1 )}^{2} + {( {ω}_{z} τ )}^{2}} = {χ}_{xxr} - {jχ}_{xxi} \qquad ( Eq . 11 )$$

where χₓₓᵣ is the real part of χₓₓ and χₓₓᵢ is the imaginary part of χₓₓ.
The imaginary part of χₓₓ/χ₀=χₓₓᵢ/χₒ is plotted in FIG. 7 versus non-dimensional frequency Ωτ for various values of ω_{z}τ. The imaginary part describes dissipative processes for χₓₓᵢ>0 which result in heating and which can be used to treat cancerous tumors. When χₓₓᵢ<0 in FIG. 7, which only happens when ωₓτ>1, the MNP suspension is pumped, resulting in mechanical work.

With particle rotation at spin velocity ω_{z}, the frequency Ω for maximum heating increases, while the amplitude of χₓₓᵢ decreases. By magnetic field adjustment of frequency Ω and spin velocity ω_{z} it is possible to magnetically control the heating rate.

The CMS tensor in Eq. 9 does not depend on linear velocity ν̅ because under the assumptions of the planar flow in FIG. 6, the second term of Eq. 5 is zero. However, other flows may have a non-zero flow velocity term in Eq. 5 and then the CMS tensor in Eq. 9 may also depend on flow velocity ν̅.

To further illustrate properties of the complex magnetic susceptibility tensor, we consider two dimensional (x, y) magnetic fields resulting in a single component of MNP spin velocity ω_{z},

H̅=Hₓīₓ+H_{y}ī_{y}, ω̅=ω_{z}ī_{z} (Eq. 12)

The resulting magnetization is then

$$\begin{matrix}{\hat{M}}_{x} = \frac{{χ}_{0} ( ( j Ωτ + 1 ) {\hat{H}}_{x} - ( {ω}_{z} τ ) {\hat{H}}_{y} )}{{( j Ωτ + 1 )}^{2} + {( {ω}_{z} τ )}^{2}} & ( Eq . 13 ) \\ {\hat{M}}_{y} = \frac{{χ}_{0} ( ( {ω}_{z} τ ) {\hat{H}}_{x} - ( j Ωτ + 1 ) {\hat{H}}_{y} )}{{( j Ωτ + 1 )}^{2} + {( {ω}_{z} τ )}^{2}} & ( Eq . 14 ) \\ {\hat{M}}_{z} = \frac{{\hat{H}}_{z}}{j Ωτ + 1} = 0 & ( Eq . 15 )\end{matrix}$$

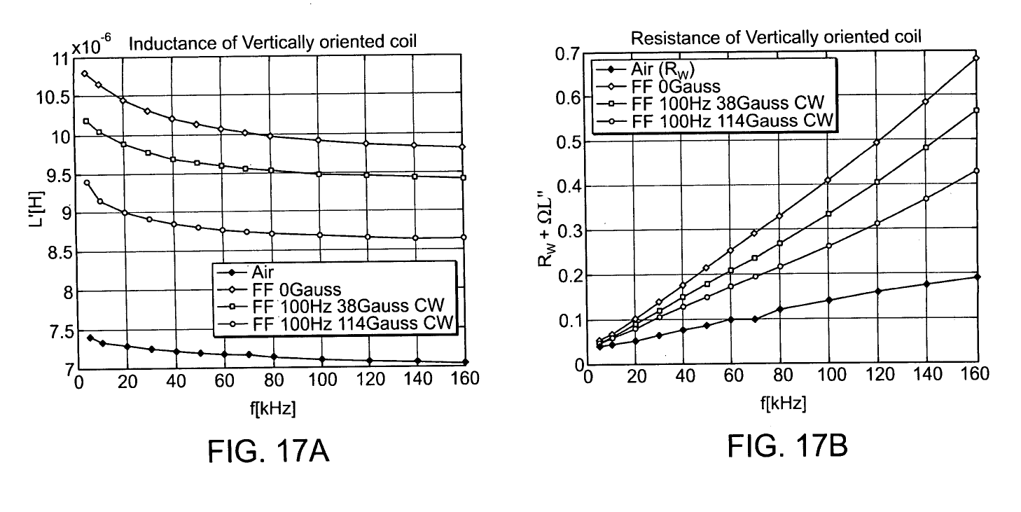

FIGS. 15A and 15B illustrate the time average power <P_{d}> for the two cases of a uniform oscillating magnetic field and a uniform rotating magnetic field, respectively. When the time average power is positive the power represents dissipation and when negative it represents fluid pumping. For both cases, the time average power <P_{d}> obeys

$$〈 {P}_{d} 〉 = \frac{1}{2} Re \{ {μ}_{0} j Ω {M}^{\hat{\_}} \cdot {{H}^{\hat{\_}}}^{*} \} \qquad ( Eq . 16 )$$

where the superscript asterisk means complex conjugate and with the non-dimensional factor P₀ given as

$${P}_{0} = \frac{{μ}_{0} {x}_{0} {H}_{0}^{2}}{τ} \qquad ( Eq . 17 )$$

For an applied, uniform, oscillating magnetic field, where Ĥₓ=Ĥ_{y}=H₀ and where H̅=H₀Re{( i̅ₓ̅+ i̅_̅{̅y̅}̅)e^{jΩτ}}, the time average power is given by

$$\frac{〈 {P}_{d} 〉}{{P}_{0}} = \frac{{( Ωτ )}^{2} ( 1 + {( Ωτ )}^{2} - {( {ω}_{z} τ )}^{2} )}{{( 1 - {( Ωτ )}^{2} + {( {ω}_{z} τ )}^{2} )}^{2} + 4 {( Ωτ )}^{2}} \qquad ( Eq . 18 )$$

For an applied, uniform, counterclockwise (CCW) rotating field, in a right-hand-rule reference frame defined by a counterclockwise sweep of a x-axis toward a y-axis in a horizontal plane generating an upward z-axis, where Ĥₓ=Ĥ₀ and Ĥ_{y}=−jH₀, the time average power is given by

$$\frac{〈 {P}_{d} 〉}{{P}_{0}} = \frac{( Ωτ ) ( Ωτ - {ω}_{z} τ )}{1 + {( Ωτ - {ω}_{z} τ )}^{2}} \qquad ( Eq . 19 )$$

In FIG. 15A, power dissipation is shown for a uniform oscillating magnetic field as a function of differing values of the product of spin velocity ω_{z} and the magnetic time constant τ. FIG. 15B shows power dissipation in a uniform rotating magnetic field as a function of differing values of ω_{z}τ. Negative spin velocities (or negative ω_{z}τ) represent counter-rotating spin and magnetic field; and positive spin velocities represent co-rotating spin and magnetic field.

According to a preferred embodiment of the invention, in order to evaluate the effect of applied DC and rotating magnetic fields on CMS tensor components of a ferrofluid, a 20-turn, 18-gauge copper wire cylindrical coil can be used. The resulting relationships of complex magnetic permeability μ, complex inductance L, and complex impedance Z are given as follows:

$$\begin{matrix}χ = {χ}^{′} - {jχ}^{″} & ( Eq . 20 ) \\ μ = {μ}_{0} ( 1 + x ) = {μ}^{′} - j {μ}^{″} & ( Eq . 21 ) \\ L = \frac{μπ {R}^{2} {N}^{2}}{d} = \frac{π {R}^{2} {N}^{2}}{d} ( {μ}^{′} - j {μ}^{″} ) = {L}^{′} - j {L}^{″} & ( Eq . 22 ) \\ Z = {R}_{w} + j Ω L = {R}_{w} + Ω {L}^{″} + j Ω {L}^{′} & ( Eq . 23 ) \\ {L}^{′} = \frac{{μ}_{0} π {R}^{2} {N}^{2}}{d} ( {x}^{′} + 1 ) & ( Eq . 24 ) \\ Ω {L}^{″} = \frac{{μ}_{0} Ωπ {R}^{2} {N}^{2} {χ}^{″}}{d} & ( Eq . 25 )\end{matrix}$$

where R_{W} is the resistance of the coil winding, R is the radius of the solenoid coil, N is the number of the turns of the coil, d is the length of the coil and Ω is the angular frequency applied by an impedance analyzer. ΩL″ is the dissipative part of the complex inductance owing to ferrofluid Brownian and Néel magnetic relaxation and acts as an additional resistance to the resistance of the copper wire coil.

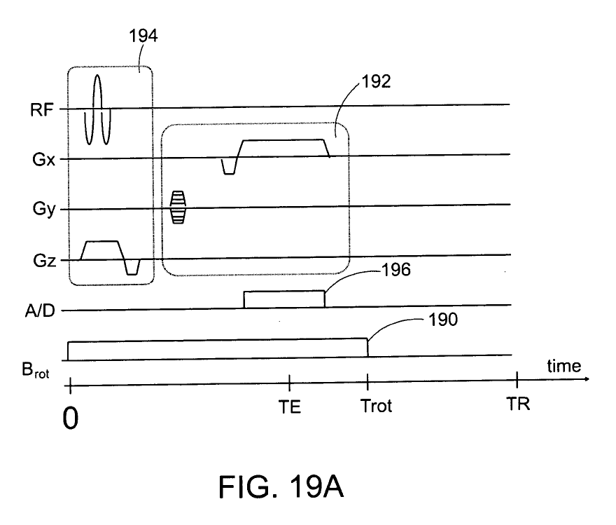

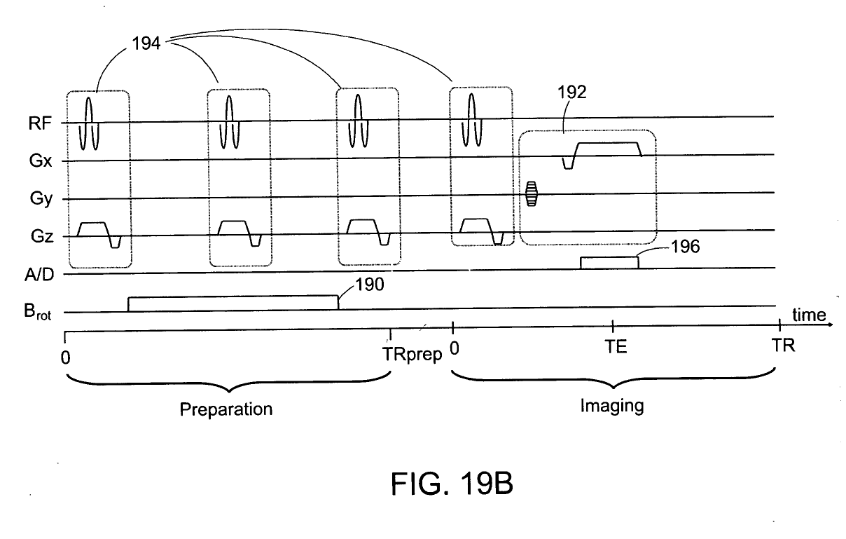

The coil complex inductance L can be first measured in air as a function of frequency using a Model 4192A Hewlett-Packard Low-Frequency (LF) Impedance Analyzer (HP, Palo Alto, Calif.) which imposes a predominantly vertical z-directed magnetic field along the coil axis. A uniform horizontally rotating magnetic field in the x-y plane can be generated by a 2 pole-3 phase AC motor stator winding, which produces no effect on the complex inductance measurement when the coil is in air. When the coil is immersed in a ferrofluid, such as, for example, in FERROTEC® MSG W11™ ferrofluid, with no applied rotating magnetic field, the complex inductance L=L′−jL″ increases from the air values by the complex magnetic permeability factor μ/μ₀=(μ′−jμ″)/μₒ as shown in FIGS. 17A and 17B. When a rotating magnetic field is applied at a frequency of 100 Hz at 38 Gauss root-mean-squared (rms), both L′ and R_{w}+ΩL″ decrease, decreasing even further at Gauss root-mean-squared (rms). FIGS. 18A and 18B show, for both clockwise (CW) and counter clockwise (CCW) rotating magnetic fields at 100 Hz and 38 Gauss rms, that an applied z-directed DC magnetic field over the range of zero to 900 Gauss causes L′ and ΩL″ to further decrease. This demonstrates tunable control of the magnetic properties of an MNP suspension using a rotating magnetic field with and without a DC magnetic field. An additional factor in the decreasing coil inductance and resistance with DC and/or rotating magnetic fields is the DC nonlinear magnetization, as given by Eq. 4. The incremental equilibrium magnetic susceptibility χ₀ decreases with increase in the magnitude of the magnetic field, due to the decreasing slope of the equilibrium M-H curve as H̅ increases.

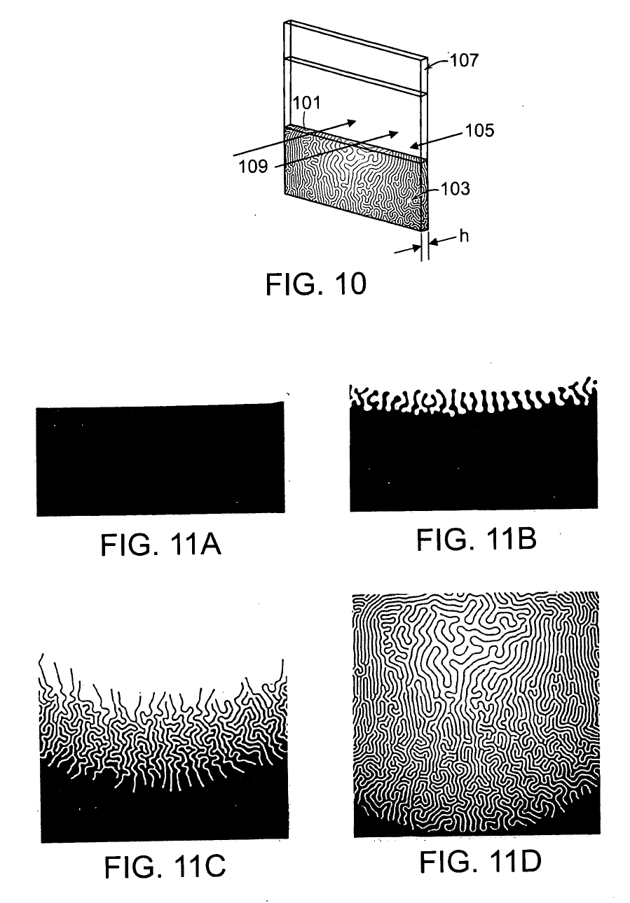

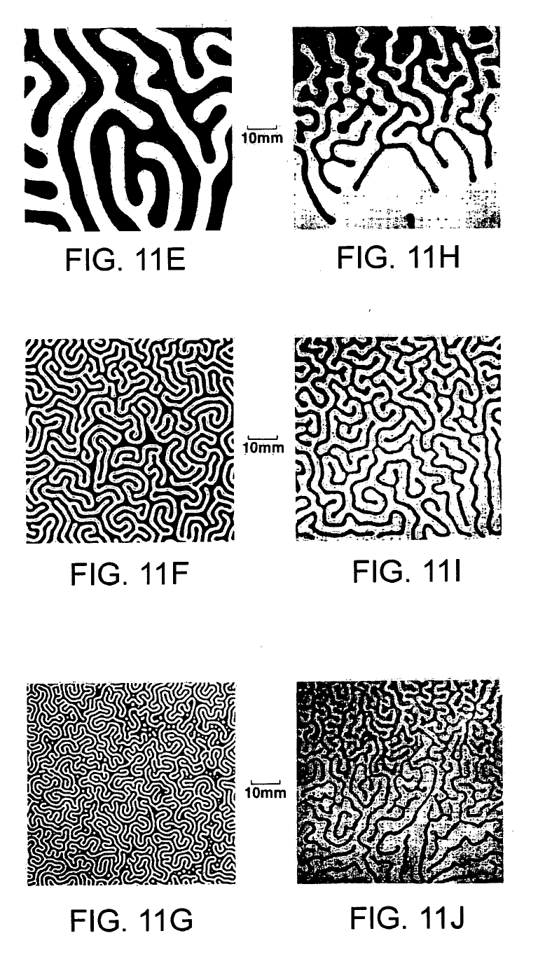

FIGS. 8A-8F and 9A-9F show progressive stages, respectively, of spiral and drop patterns resulting from particle spin effects, where a ferrofluid drop is placed in a thin-layer glass (Hele-Shaw) cell of 1.1 mm gap and in-plane, clockwise rotating (20 Gauss rms at 25 Hertz) and vertical DC (0-250 Gauss) magnetic fields are simultaneously applied, with a DC coil resistance R_{w}=0.03 ohms, for example. The ferrofluid is surrounded by propanol to prevent glass smearing. In FIGS. 8A-8F, the vertical DC field is first applied to form the labyrinth pattern, branching radially outward, and then the rotating field is applied to form additionally a spiral pattern. In FIGS. 9A-9F, the rotating field is applied first and then, as the DC magnetic field is increased to about 100 Gauss, the continuous fluid drop abruptly transitions to discrete droplets. The first three images in each case (FIGS. 8A-8C and FIGS. 9A-9C) show the progress of a single mixing evaluation. The final three images (FIGS. 8D-8F and 9D-9F) depict three end states for three different mixing demonstrations, respectively.

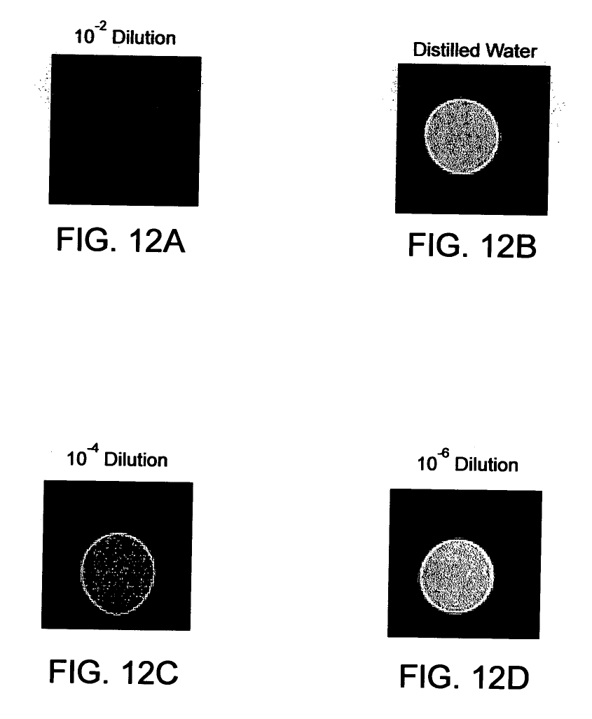

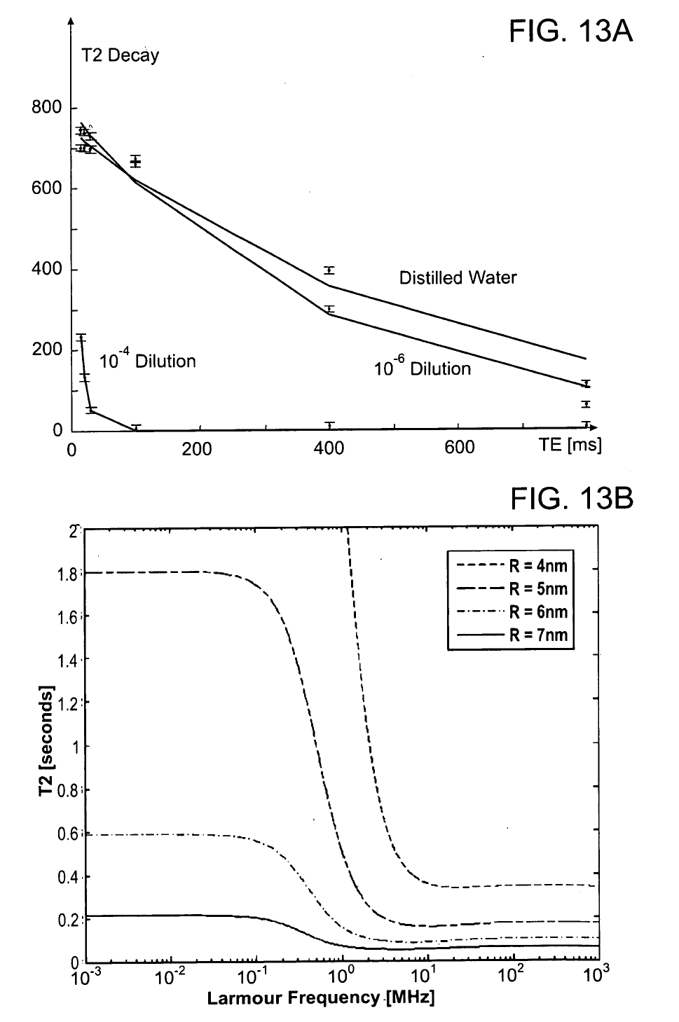

FIG. 10 depicts schematically a boundary 101 between a magnetic fluid 103 and a non-magnetic fluid 105, arranged in a vertical thin-layer cell 107, being 75 mm on a side with gap h=1 mm, with a uniform magnetic field 109 applied tangentially to the thin dimension. FIGS. 11A-11D illustrate the progressive stages that result, as the magnetic field is ramped from zero to 535 Gauss, where the magnetic fluid is caused to moved across the boundary into the non-magnetic fluid, forming intricate, labyrinthine patterns [See, for example, R. E. Rosensweig, Ferrohydrodynamics, Cambridge University Press, 1985; Dover Publications, Inc., Mineola, N.Y., 1997, pp. 208-216; and R. E. Rosensweig, M. Zahn, and R. Shumovich, “Labyrinthine instability in magnetic and dielectric fluids”, Journal of Magnetism and Magnetic Materials, 39 (1, 2), pp. 127-132, these being incorporated herein by reference].

FIGS. 11E-11J show the duality of behavior between magnetic fluid in a magnetic field (FIGS. 11E-11G) and a dielectric fluid in an electric field (FIGS. 11H-11J) for various field strengths and gap spacings. FIG. 11E shows a pattern produced at low magnetic field and large gap (0.01 Tesla, 0.9 mm, respectively), FIG. 11F shows a pattern produced at high magnetic field and large gap (0.035 Tesla, 0.9 mm) and FIG. 11G shows a pattern produced at high magnetic field and small gap (0.035 Tesla, 0.4 mm). FIG. 11H shows a pattern produced at low electric field and large gap (10 kV/cm, 1.6 mm, respectively), FIG. 11I shows a pattern produced at high electric field and large gap (16 kV/cm, 1.6 mm) and FIG. 11J shows a pattern produced at high electric field and small gap (16 kV/cm, 0.8 mm). Embodiments of the invention can create these types of patterns, among many other types of patterns, in controllable sequences and localized regions of interest and application.

In a rotating magnetic field, the magnetization relaxation time constant τ (See, Eq. 1) causes a phase difference between magnetization and magnetic field so that M̅ and H̅ are not in the same direction. This causes a magnetic torque density given by T̅=μ₀ M̅× H̅ which causes the magnetic nanoparticles and surrounding fluid to spin, which causes controllable microdrop behavior, such as that shown in FIGS. 8A-8F and 9A-9F, above. This behavior, and variations of similar behavior created by admixing other tuning fields, can be used for biological applications to magnetically steer, hold and manipulate magnetic nanoparticles, e.g., to free trapped particles in the body, or to increase local fluid mixing to enhance diffusion processes.

In an MRI system, the value of the magnetic susceptibility affects the values of T1 and T2 which control MRI contrast. Pierre Gillis et al. [P. Gillis, A. Roch, and R. A. Brooks, “Corrected Equations for Susceptibility-Induced T2-Shortening,” Journal of Magnetic Resonance, Vol. 137, 1999, pp. 402-407], incorporated herein by reference, have derived and experimentally verified theoretical predictions of how paramagnetic particles affect T1 and T2

$$\begin{matrix}1 / T 1 = \frac{16 π}{135000} {γ}^{2} {N}_{A} C {μ}_{m}^{2} \frac{{τ}_{d}}{{d}_{3}} \{ 3 {L}^{2} ( α ) {J}_{0} ( {ω}_{0} , {τ}_{d} , τ \to ∞ ) + 3 [ 1 - 2 \frac{L ( α )}{α} - {L}^{2} ( α ) ] {J}_{0} ( {ω}_{0} , {τ}_{d} , τ ) \} & ( Eq . 26 ) \\ 1 / T 2 = \frac{16 π}{135000} {γ}^{2} {N}_{A} C {μ}_{m}^{2} \frac{{τ}_{d}}{{d}^{3}} \{ {L}^{2} ( α ) [ 3 {J}_{0} ( {ω}_{0} , {τ}_{d} , τ \to ∞ ) + 4 {J}_{0} ( 0 , {τ}_{d} , τ \to ∞ ) ] + [ 1 - 2 \frac{L ( α )}{α} - {L}^{2} ( α ) ] [ 3 {J}_{0} ( {ω}_{0} , {τ}_{d} , τ ) + 4 {J}_{0} ( 0 , {τ}_{d} , τ ) ] \} \\ where & ( Eq . 27 ) \\ {J}_{0} ( ω , {τ}_{d} , τ ) = \{ \frac{1 + 0.25 {Ω}^{0.5}}{1 + {Ω}^{0.5} + ( 4 / 9 ) Ω + ( 1 / 9 ) {Ω}^{1.5}} \} \\ and & ( Eq . 28 ) \\ Ω = ( j ω + 1 / τ ) {τ}_{d} & ( Eq . 29 )\end{matrix}$$

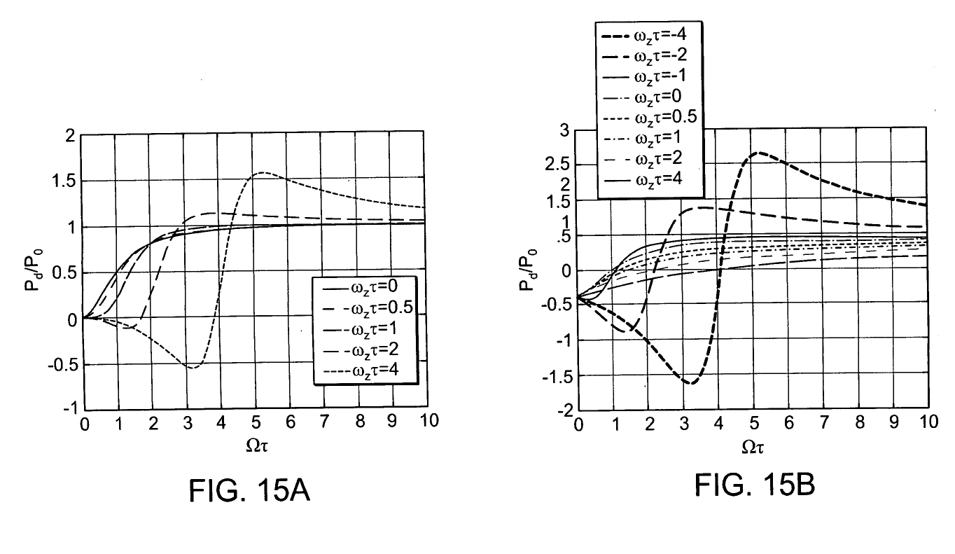

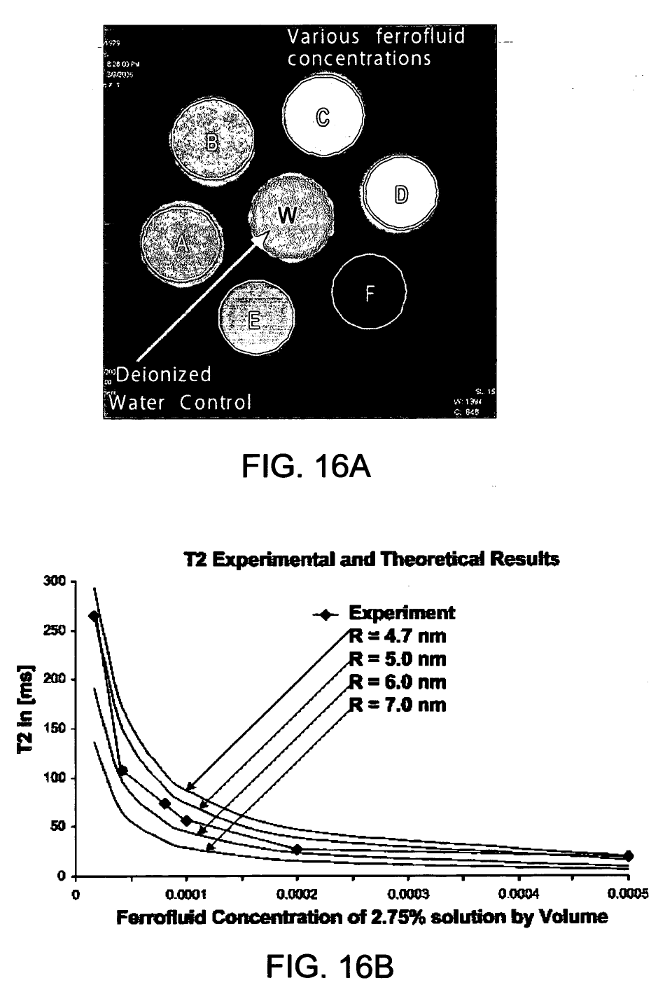

and with variables and constants as follows
N_{A}=Avogadro's constant
C=molar concentration of contrast agent
μₘ=M_{d}V=magnetic dipole moment
ω₀=proton Larmor frequency
τ_{d}=diffusion time constant
d=closest distance of approach
J₀=power spectral density function
τ=ferrofluid time constant
   and α is the Langevin argument given in Eq. 4, above. FIGS. 13B and 14B show how T2 and T1 vary with Larmor frequency, γB₀, as given by Eqs. 26-29, where γ=42.58 MHz/Tesla is the gyromagnetic ratio for protons and B₀ is an applied DC magnetic field, for various nanoparticle radii of magnetite with volume concentration in water of 3.78×10⁻⁸.

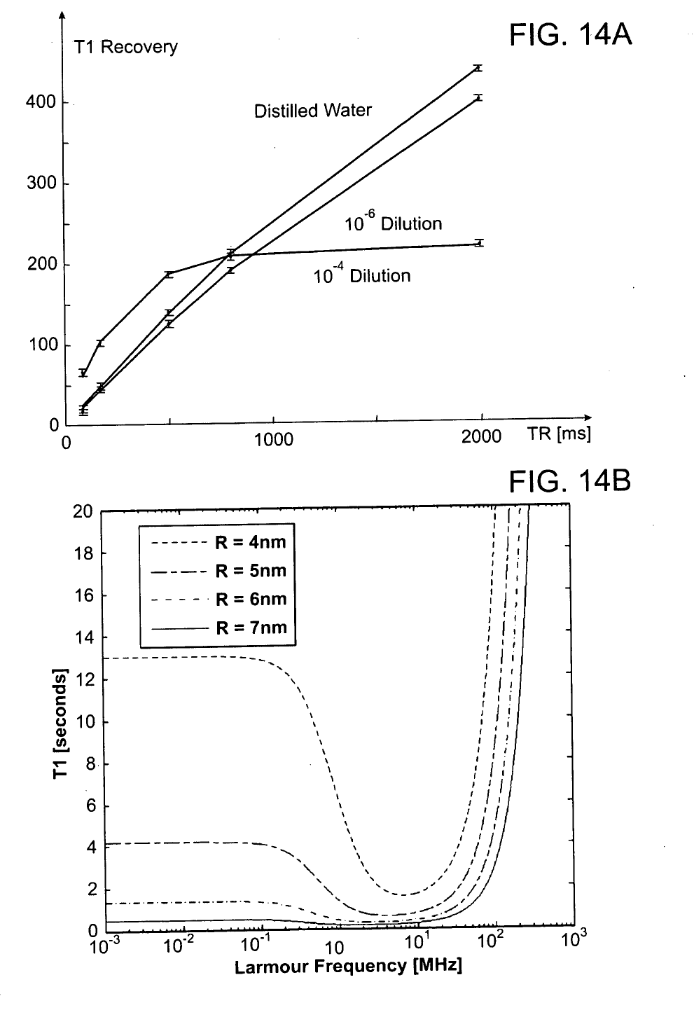

According to a preferred embodiment of the invention, ferrofluids can be used as potent MR contrast agents by measuring MR relaxation parameters in a clinical MRI scanner. With MR imaging of ferrofluids in a clinical 1.5 T scanner, the relaxation effects of a ferrofluid can be illustrated when the ferrofluid is used as an MR contrast agent. FIGS. 12A-12D show vials in an MRI phantom constructed to demonstrate the effect of differing magnetic fluid concentrations on MRI time constants T1 and T2. A 3% solution of ferrofluid (Magnetite) was diluted in distilled water to produce 20 cc vials with concentrations of 10⁻², 10⁻⁴, and 10⁻⁶ of the original solution, and scanned along with a control sample of distilled water. FIG. 12A shows the 10⁻² dilution and by its signal void shows that the ferrofluid is a strong negative contrast T2 agent. FIG. 12B shows distilled water. FIGS. 12C and 12D are the 10⁻⁴ and 10⁻⁶ dilutions, respectively. Comparing FIGS. 12B and 12D the 10⁻⁶ dilution ferrofluid image appears slightly brighter than the distilled water, which demonstrates that the ferrofluid can serve as a positive contrast agent under certain conditions, owing to T1 shortening (i.e., if the image is acquired at a very short TE, and thus relatively longer T2, as in this example). The ferrofluid modulation of T1 provides an effect that diminishes in relative contribution to the overall image compared with modulation of T2 as T2 gets very short (which occurs at the relatively higher concentrations of the ferrofluid). The T1 effects are most noticeable in the T1 recovery curve for the 10⁻⁴ dilution vial in FIG. 14A.

The quantitative results in tabular format are as follows:

TABLE 1
Results of ferrofluid at differing dilutions in
MRI phantom affecting T1 and T2 time constants.

| Dilution | T1 (ms) | T2 (ms) |
|---|---|---|
| Water | 3200 | 570 |
| 10⁻⁶ | 3000 | 410 |
| 10⁻⁴ | 260 | 11 |
| 10⁻² | <<10 | <<1 |

As shown in FIG. 13A, T2 was estimated by a fit to signal decay, e^{-TE/T}2 with increasing echo time delay, TE, where repetition time TR was held constant at 5 s. The estimated values for T2 were 570 ms, 410 ms, and 11 ms for the distilled water, 10⁻⁶, and 10⁻⁴ dilutions respectively. The relatively faster decay of the MR-visible signal intensity with increasing TE shows that the 10⁻⁴ solution clearly has a dramatically shorter T2 than the distilled water and the 10⁻⁶ solution. At 10⁻² dilution, T1 and T2 are so short that they are not measurable by conventional clinical technology.

Referring to FIG. 14A, T1 was estimated by a fit to signal intensities, 1−e^{-TR/T1}, from a series of spin-echoes with increasing repetition times, with TE held constant at 14 ms. For the same vials, T1 was estimated at 3200 ms, 3000 ms, and 260 ms. Signal recovery with increasing repetition time TR shows substantial shortening of T1 apparent for the 10⁻¹ diluted ferrofluid. These results demonstrate the dramatic impact of even low concentrations of ferrofluid on the MR relaxation times, T1 and T2, the parameters that form the basis for image contrast in most clinical applications of MRI.

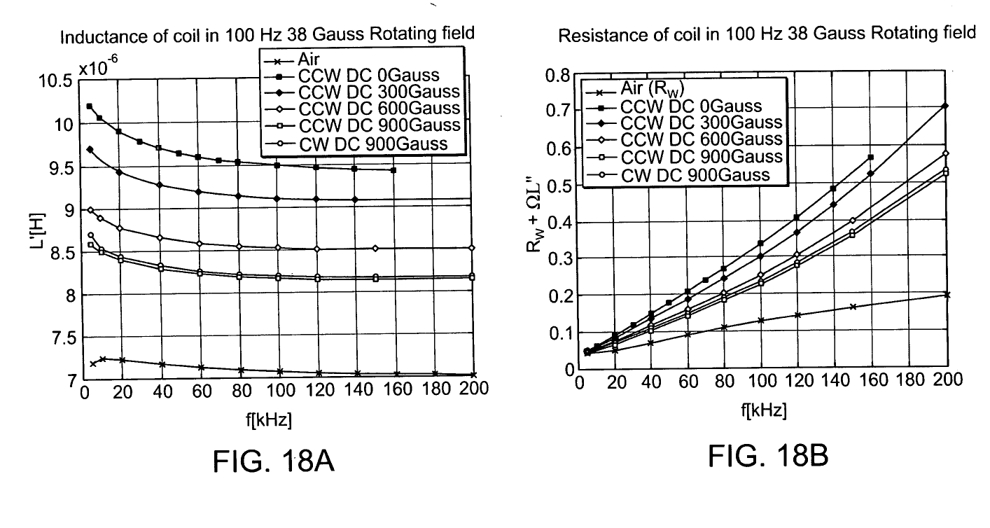

FIG. 16A shows more extensive vial measurements with different ferrofluid concentrations in an MRI phantom at 1.5 Tesla. Through careful selection of the TR and TE times, the dependence of T1 and T2 as a function of the ferrofluid concentration, C, was obtained as given in Table 2 and fitted to the concentration power laws of Eqs. 30 and 31, below.

TABLE 2
Measured T1 and T2 results for various ferrofluid concentrations
of 2.75% solution of MSG W11 supplied by Ferrotec.

| Vial | Concentration, C | T1 [ms] | T2 [ms] |
|---|---|---|---|
| A | 1.7 × 10⁻⁵ | 1706 | 265 |
| B | 4.2 × 10⁻⁵ | 1345 | 108 |
| C | 8 × 10⁻⁵ | 1009 | 74 |
| D | 1 × 10⁻⁴ | 887 | 57 |
| E | 2 × 10⁻⁴ | — | 27 |
| F | 5 × 10⁻⁴ | — | 20 |

T1=75.471 C^{-0.2851} (Eq. 30)

T2=0.0419 C^{-0.7872} (Eq. 31)

FIG. 16B compares the experimental values of T2 from Table 2 to the theory given by Eq. 27 for various particle sizes. The theory and measurements agree for particle radii in the 5-6 nm range.

A preferred method of the invention takes advantage of the facts that T1 and T2 change in the presence of ferrofluid and that the complex magnetic susceptibility of the ferrofluid changes with DC magnetic field and with nanoparticle spin velocity which can be controlled with imposed rotating magnetic field amplitude and frequency or flow vorticity. This procedure can provide in vivo imaging of targeted delivery and monitoring of remotely induced hyperthermia. In this instance, the method includes modulating an applied rotating magnetic field to change the ferrofluid magnetic susceptibility tensor and thereby modulate the MRI field(s) to cause intermittent fluctuations in image contrast so that the location of the magnetic nanoparticles can be easily seen. If the nanoparticle surface coating is functionalized to be selectively adsorbing to specific media, such as a tumor, then the particles also can provide an effective cancer therapy. The temporal modulation of signal intensity (i.e., intermittent fluctuations in image contrast) identifies the location of the tumor, which can then be treated by magnetic nanoparticle heating.

Additional sources of contrast in MRI imaging, in addition to the T1 and T2 time constants discussed above, include T1_{τ}, T2_{τ}, and T2*. T1_{τ} and T2_{τ} are contrast mechanisms that are enhanced by applying a rotating field at or near the Larmor frequency in a preparation stage prior to imaging. T1_{τ} is a variant on T1 caused by inducing a restricted form of T1 decay caused by the Larmor spin precession tracking the rotational field (see FIG. 2A). T2_{τ} is a spin relaxation orthogonal to T1_{τ}. T2* is a modified transverse relaxation time due to gradients in magnetic field as given in FIG. 2D. T2* is the term most likely to be affected by relatively low-frequency MNP spin. At higher field strengths (>3.0 Tesla) the susceptibility gradients that lead to T2* shortening increase linearly with the main field (to first order) causing a shortening of T2* at higher fields. T2 and T2* weighted images are strongly influenced by blood oxygenation state. This leads to better T2* contrast in applications like blood oxygen level dependent (BOLD) imaging. BOLD contrast, used to map function in the brain, gets a boost both from the increased signal-to-noise ratio (SNR) and the increased T2* contrast. However, a disadvantage is that shortened T2* values also lead to signal loss for long TE gradient echo acquisitions and cause challenges for echo-train based acquisition techniques, such as echo-planar imaging (EPI).

A preferred embodiment of the invention provides for external manipulation and induced heating of the ferrofluid by external DC, time-varying, and rotating magnetic fields. The interaction of the magnetic fields associated with MR with those magnetic fields required for nanoparticle manipulation and hyperthermia establishes a viable range of frequency for time-varying manipulation and heating fields. The rate of heating of ferrofluid also depends on the magnetic susceptibility. The maximum value of heating rate depends on the nanoparticle spin velocity and the frequency.

Hyperthermia (heating) in this context can be of interest as cancer therapy, but it will find other uses, such as enhancing drug efficacy or mediating drug delivery. The change in the imaginary part of the complex magnetic susceptibility in the presence of an AC magnetic field, shown in FIG. 7, is used to optimize the heating rate. Hyperthermia can be obtained by rotating the magnetic nanoparticles (Brownian motion) or by rotating the magnetic moment without rotation of the particle (Néel relaxation) or both. The rate of heating can be controlled by the amplitude, frequency, phase and direction of the rotating magnetic field (and/or by DC and/or an oscillating linearly-polarized, nonrotating magnetic field or any time dependent magnetic field, inter alia) and can be applied to selective cell magnetocytolysis. For example, tumor cells can be killed in the temperature range of about 41-46 degrees C. without harming healthy cells.

A preferred embodiment of the invention also provides for hypothermia (cooling) using the temperature dependence of ferrofluid magnetization through the magnetocaloric effect where cooling occurs when a magnetic field is removed, known as magnetic refrigeration or magnetic heat pumping.

By magnetic field control of the magnetic nanoparticle spin velocity a preferred embodiment of the invention can control the flow velocity around the particles to cause mixing and to enhance diffusion processes. This can, for example, enhance the rate of drug delivery. FIGS. 8A-F, 9A-F, 10, and 11A-J above, illustrate aspects of enhanced mixing.

An embodiment of the invention uses particle spin velocity for therapeutic effect. An imposed rotating magnetic field is a preferred way to control the particle spin velocity. However, the spin velocity also depends on flow vorticity and blood flow has vorticity (Poiseuille flow); this offers another way to use the invention without the use of an additional activation magnetic field over what is already present in conventional MRI machines. However, a preferred embodiment of our device uses the additional activation rotating magnetic field.

A preferred method of the invention can include the following steps:
(a) prepare magnetic nanoparticles with correct size so that the relaxation time τ and the preferred magnetic field frequency f of the operation is optimized for heating such that, where Ωτ=2πfτ, 2πfτ is equal to or substantially equal to unity in the carrier liquid (such as, e.g., water or other vehicle) when ω̅=0. The optimum frequency increases as spin velocity increases, as shown in FIG. 7.
(b) choose surfactant or surface coating to both colloidally stabilize the ferrofluid as well as to be functionalized for the desired biomedical application such as selective adsorption in vivo or in vitro of drugs, proteins, enzymes, antibodies, organisms, body organs, tumors, diseased tissue, inter alia; hyperthermia; magnetocytolysis of cancerous tumors; separations and cell sorting; immunoassays; enhanced MRI; inter alia.
(c) inject optimized ferrofluid into the body and view by MRI or by pre-polarized MRI (pMRI) or by functional MRI (fMRI).
(d) optimize the biomedical process by applying an activation oscillating or rotating magnetic field (in addition to those required for MRI or pMRI) or by a fluid (e.g., blood) flow to cause magnetic nanoparticles to spin thereby changing the effective complex magnetic susceptibility;
(e) increase or decrease the fluid velocity by changing the primary and/or activation magnetic field amplitude(s), frequency, phase or direction; and/or periodically turn on and off the exciting magnetic field, therefore introducing known, externally controllable, temporal variation in signal strength at the location of the MNPs and MNP vehicle carrier fluid (or ferrofluid agent) so that the MR image fluctuates intermittently where the ferrofluid agent is located, thereby identifying the ferrofluid location and associated attachment location that has the designed preferential binding (e.g., tumor location);
(f) enhance the functionality of the ferrofluid agent by external magnetic field, such as controlling and optimizing position (as opposed to conventional passive delivery in vivo) of the injected bolus, increasing or activating binding, preventing binding, enhancing transport and/or enhancing functional reaction through heating, and/or optimizing time rate of functional interaction; and
(g) magnetically manipulate, externally, the ferrofluid agent in order to move the agent into or out of a region of interest (e.g., during application of hyperthermia) for improved therapy monitoring and/or improved visualization.

Contrast-tuning with a ferrofluid contrast agent can be accomplished by magnetic field control of the scalar or tensor complex magnetic susceptibility through its dependence on the magnetic nanoparticle spin velocity and/or flow velocity, inter alia. This can be done by controlling the amplitude and frequency of the rotating magnetic field acting upon the ferrofluid agent. Another method, according to a further preferred embodiment of the invention, is to control the vorticity of the ferrofluid flow.

Steering and localization can be done with an external DC or AC non-uniform activation magnetic field, or with a traveling or rotating non-uniform activation magnetic field (created by multi-pole windings beyond two pole such as four, six, eight, etc. pole windings) so that the magnetic material is attracted to strong field regions.

Since the MRI time constants T1 and T2 depend on the magnetic susceptibility, and since a preferred method according to the invention controllably changes (i.e., tunes) the magnetic susceptibility through changing spin velocity and/or linear velocity, and additionally since the preferred method provides for control of spin velocity and/or linear velocity with tuning magnetic field amplitude, frequency, phase and/or direction, therefore the preferred method provides for observable, temporal modulation of MRI signal intensity (including intermittent fluctuations being caused in the image) by modulating the spin velocity and/or linear velocity, inter alia, through controlling magnetic field amplitude, frequency, phase and direction. For example, if the magnetic nanoparticles have a selective adsorbing coating to a tumor, the MNPs can be located by observing the intermittent fluctuations in MRI signal intensity. Then, further therapeutic treatment can be performed, such as hyperthermia to kill the tumor.

For hyperthermia treatment, the approximate optimum value for the radian frequency of rotating magnetic fields is 1/τ where τ is the magnetic relaxation time due to Néel and Brownian relaxation as given by Eq. 1. These time constants depend on particle volume and so are very dependent on particle size and shape. For example, a 10 nm diameter spherical particle with a typical value of τ approximately equal to 10 microseconds results in an optimum frequency in the range of 10-20 kHz, preferably about 16 kHz. Changes in particle size, shape, particle agglomeration, binding to fixed surfaces, inter alia, can change this frequency up or down by many orders of magnitude. For example, when a magnetic nanoparticle is attached to a wall owing to an adsorbing coating, then the magnetization relaxation time is only due to Néel relaxation, so For magnetite τ=τ_{N}=τ₀e^{(KV}^{ₚ}^{/kT)}. For magnetite τ₀≈10⁻⁹ s and K≈78,000 J/m³ at room temperature. As the particle diameter varies from 5.5 nm to 12.4 nm τ_{N} varies from 5.2×10⁻⁹ s to 0.15 s. The optimum frequency for heating then varies from 3×10⁷ Hz to 1 Hz. The optimum frequency increases further with increasing spin velocity ω̅, which can be seen in FIG. 7.

As shown here, when operating in the RF range, such as near or about 30 MHz range of our example, MNPs can respond to NMR signals used to excite protons or other nuclei. With MNPs engineered to have characteristic frequencies in a range of about 30 MHz or higher according to preferred embodiments of the invention, conventional magnetic resonance RF can be used to produce MNP driving fields at Larmor frequencies for nuclei of multiple chemical species that exhibit nuclear magnetic resonance (e.g., ¹H, ¹³C, ³¹P, ¹⁹F, ¹⁷O and ²³Na).

Embodiments of the invention can provide particular advantage in the domain of low-field MRI. Low-field MRI applications are often starved for signal strength, due to lower B₀ fields and lower RF excitation intensity, and therefore previously these applications have been lower in intervention efficiency and imaging quality. Examples of useful low-field applications include decoupling, spin-locking and arterial spin labeling. Decoupling involves destroying coherence between two atomic components having different spin characteristics, for example between protons and C-13. In a low-field setting, the imaging must rely on an induced field to amplify the decoupling field. Spin-locking involves matching a resonant frequency of spin with the frequency of a driving field, thus shifting the recovery time and enhancing imaging.

Enhancing a spin-locking field with MNPs tuned to the spin-locking frequency (which is a sensitive function of the Larmor frequency) allows MNP effects to be realized with lower power external fields applied. By essentially making “larger protons” (shifting the resonant frequency) and modeling as a dipole reconstruction of MR images can be enhanced at lower power settings. A preferred embodiment of the invention, therefore, provides for picking one spin-locking frequency (typically in the neighborhood of the Larmor frequency), locking this frequency to the driving field (for example, a rotating magnetic field), and causing an intervention or useful interaction in the kHz range (e.g. 12-18 kHz), for example, where the Néel relaxation is a very sensitive exponential function of the particle volume. This method illustrates the importance of selecting optimal particle size.

Arterial spin labeling techniques utilize the intrinsic protons of blood and brain tissue, labeled by special preparation pulses, rather than exogenous tracers injected into the blood; this involves polarity oscillations from a +M_{z} gradient field to a −M_{z} gradient field and a demanding RF power application, but the large RF power requirement brings regulatory safety concerns for example such as those concerns relating to the Specific Absorption Rate (SAR) limitations on RF power absorption by humans mandated by the U.S. Food and Drug Administration.

Benefits of applying the method of the invention in low field MRI conditions under 0.5 Tesla, such as, for example, in 0.1 Tesla MRI systems, include allowing enhancing imaging while B₀ can be in the range of Bᵣₒₜ, increasing patient safety, increasing portability (smaller overall apparatus) and lowering operational cost (less power and less cooling required).

A preferred method of the invention further comprises having a magnetic field frequency (MFF), preparing MNPs having magnetic material radius, R_{P}, and overall radius, Rₕ, with V, being the volume of the magnetic material in an MNP generated by radius R_{P}, Vₕ being the hydrodynamic volume of carrier fluid displaced by an MNP generated from the radius Rₕ=Rₚ+δ, K being the particle magnetic anisotropy energy, n being the carrier fluid viscosity, k=1.38×10⁻²³ Joules/Kelvin being the Boltzmann factor, T the temperature in degrees Kelvin, τ₀ typically around 10⁻⁹ seconds in magnetite, and τ being the net magnetic relaxation time constant derived from the relationship

$$\frac{1}{τ} = [ \frac{1}{3 η {{V}_{h} ( kT )}^{- 1}} ] + [ \frac{1}{{τ}_{0} {e}^{( {KV}_{p} / kT )}} ] \qquad ( Eq . 32 )$$

such that the product of the magnetic field frequency (MFF) in Hertz and the magnetic relaxation time constant (τ) in seconds is approximately equal to 1/2π when ω̅=0. The optimum MFF increases as ω̅ increases as shown in FIG. 7.

Another preferred embodiment of the invention provides for specific applications of ferrohydrodynamics to the human body for therapeutic purposes. The force density, including compressibility, for magnetically linear and non-linear media, is

$$\overline{F} = \{ \begin{matrix}\overline{J} \times \overline{B} - \frac{{H}^{2}}{2} ∇ μ + ∇ ( \frac{ρ}{2} \frac{\partial μ}{\partial ρ} {H}^{2} ) , & \overline{B} = μ ( ρ ) \overline{H} \\ \overline{J} \times {μ}_{0} \overline{H} + {μ}_{0} ( \overline{M} \cdot ∇ ) \overline{H} + ∇ ( {p}_{S} ) , & \overline{B} = {μ}_{0} ( \overline{H} + \overline{M} ( υ ) ) \cdot υ = \frac{1}{ρ}\end{matrix} \qquad ( Eq . 33 )$$

where J̅ is current density (amp/m²), ν is the specific volume, and ρ_{S} is the magnetostrictive pressure given by

$${p}_{S} = ∇ ( {μ}_{0} {\int }_{0}^{H} \frac{\partial ( \overline{M} υ )}{\partial υ} \cdot d \overline{H} ) \qquad ( Eq . 34 )$$

B̅=μ(ρ) H̅ in magnetically linear fluid media, where the magnetic permeability μ(ρ) depends on the mass density ρ.

This procedure can include placing MNPs into the bloodstream, where the magnetic diffusion time τ_{d}=σμl², the penetration of external magnetic fields, known as the skin depth, δₛ=(2/Ωμσ)^{1/2}, and the magnetic Reynolds number Rₘ=σμl²/(l/ν)=σμlν, where l is a characteristic length, μ is the magnetic permeability and σ is the ohmic conductivity of the blood, Ω is the magnetic field radian frequency, and ν is the blood velocity. In one preferred embodiment, parameter values for bloodstream applications are given by

ν=4.25 m/s (aorta)

σ=0.7 Siemens/m

ρ≈μₒ=4π×10⁻⁷ Henry/m

l≈0.01 m

For external activation of magnetic fields to penetrate the body, in this embodiment of the method of the invention, we evaluate the skin depth as defined above, as τ=88 ps, Rₘ=3.7×10⁻⁸, and magnetic field penetration distance into the body δₛ=19 m at 1 KHz. With τ essentially instantaneous, the magnetic Reynolds number much less than one, and with magnetic field penetration distance δₛ much greater than the thickness of a human body, the imposed magnetic fields according to the invention will effectively completely penetrate into the body. To be shielded by a portion of the body and thus prevent penetration of the magnetic field into the central volume of the body, the skin depth δₛ would have to be less than about 1 centimeter. For the parameter values of this embodiment this requires a frequency higher than 3.6 GHz.

Another preferred embodiment of the method of the invention provides for achieving stability against agglomeration of the MNPs in the magnetic field. Stability factors will include functions of the thermal energy, kT, and the magnetic energy, μ₀M_{d}HVₚ where

k=1.38×10⁻²³ Joule/K=Boltzmann's constant

T=temperature in degrees Kelvin

μ₀=4π×10⁻⁷ Henry/meter=magnetic permeability of free space

M_{d}=particle magnetization in Ampere/meter

H=magnetic field in Ampere/meter

Vₚ=(4πRₚ³)/3=magnetic volume of each spherical MNP

A condition for establishing magnetic particle stability against agglomeration is provided in a preferred embodiment of the invention, and is given by

$$\frac{kT}{{μ}_{0} {M}_{d} H ( π {d}^{3} / 6 )} > 1 ⇒ d < {( \frac{6 kT}{{πμ}_{0} {M}_{d} H} )}^{1 / 3} \qquad ( Eq . 35 )$$

where

M_{d}=4.46×10⁵ A/m (equivalently μ₀M_{d}=0.56 Tesla) for magnetite

H=10⁴ A/m (μ₀H≈0.013 Tesla=130 Gauss)

T=298 K

so that the preferred particle diameter, d=2Rₚ, is calculated to be d<11.2 nm.

Referring again to FIG. 1, the system 1 of a preferred embodiment of the invention consists of an MRI scanner for imaging of injected nanoparticles as a contrast agent in combination with additional apparatus for steering the external magnetic field relative to a desired location (identified by imaging), followed by magnetically induced hyperthermia (monitored by imaging). Referring still to FIG. 1, a preferred embodiment of the magnetic field tunable MRI system 21 includes a conventional MRI machine that includes a DC magnet apparatus 3 for generating a magnetic field, a gradient magnetic field generating apparatus 12 for creating a gradient magnetic field with partial components in the x, y and z directions for spatial encoding, an image display device 2, a programmable computer 4, and a radio-frequency (RF) apparatus 5 including a radio-frequency (RF) signal transmitter 6 and receiver 8 for effecting and detecting, respectively, magnetic resonance and relaxation within the magnetic field generated by apparatus 3 (such a conventional MRI machine can include a 1.5 T Siemens (Erlangen, Germany) SONATA™ whole-body clinical MRI with gradient strength of 40 mT/m and slew rate of 200 T/m/s, and a 4 RF channel phased array receiver system, or a General Electric Corp. (Waukesha, Wis.) 1.5 T LX. NVI/CVI MRI machine, version 8.3×, with gradient strength of 40 mT/m and slew rate of 150 T/m/s), an injector 7 for injecting into a patient's body a biocompatible (most likely water-base) ferrofluid, an activation magnet apparatus 9 for generating a rotating magnetic field, an activation magnetic field controller unit 10, and a controllable power supply 13 capable of modulating the frequency, amplitude, phase and/or direction, inter alia, of the activation magnetic field(s). The computer 4 also includes detection feedback software to optimally control the MRI apparatus and activation apparatus. In a preferred embodiment, activation amplitude is controlled by current in a winding, frequency and phase controlled by a power supply, and magnetic field direction determined by the design and orientation of windings.

The activation apparatus can also include permanent magnets that are moving, rotating, and/or stationary, to create any desired type of magnetic field such as DC, oscillating, traveling, and/or rotating, inter alia. Controllable permanent magnets that can be turned on or off and can have the magnetic field magnitude controlled can also be used within the activation apparatus. Such controllable permanent magnets are available from Magswitch Inc. (Littleton, Colo.).

Referring still to FIG. 1, an activation rotating magnetic field apparatus 9 can be of at least two types: uniform magnetic field or non-uniform magnetic field. A uniform activation rotating magnetic field apparatus generally consists of balanced multiphase currents with a two-pole winding (which can include a permanent magnet assembly). Simplest activation electromagnets consist of two windings which are each two-pole: one winding creates an x-directed uniform magnetic field and the other winding creates a uniform y-directed magnetic field. One winding is excited with a current that varies with time as I₀ sin(Ωt) and the other winding has a current that varies as I₀ cos(Ωt), where I₀ is the peak current in each winding. Such a pair of windings creates a magnetic field that rotates in the x-y plane. By appropriate control of the relative polarity of the currents in the two windings, the magnetic field can rotate clock-wise (CW) or counter-clockwise (CCW). Three or more two-pole windings can also be used requiring appropriate relative orientation, relative phases, and amplitudes of the currents to create a uniform rotating magnetic field in the x-y plane. Four-pole, six-pole, eight-pole, etc. machines can create rotating non-uniform magnetic fields which can be used to localize and steer particles where magnetic particles are attracted to strong magnetic field regions and non-magnetic particles are attracted to weak magnetic field regions. Ferrofluids that also have non-magnetic particles are called “negative” ferrofluids. Similarly, dielectric particles with dielectric constant greater than the carrier liquid are attracted to regions with strong electric field while particles with lower dielectric constant than the carrier liquid are attracted to regions of weak electric field. Linear machines with traveling wave windings can similarly transport magnetic or dielectric media along a line.

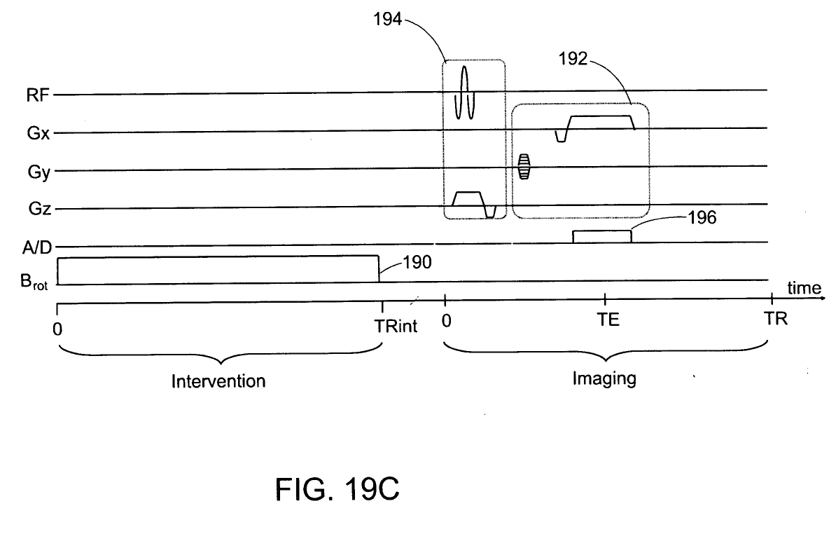

FIG. 19A shows an example of the timing or pulse sequence of a preferred method of employing an activation magnetic field with an MRI system, wherein Bᵣₒₜ is an activation rotating magnetic field applied to induce particle spin velocity which causes changes in the magnetization of an MNP suspension that consequently changes in the complex valve of the CMS. A data-acquisition sequence (the “A/D” sequence) is initiated near time TE, wherein analog data is collected and then converted to digital form, with the digital data being used to enable an imaging operation and further data processing. Sequence 194 indicates excitation at the Larmor frequency, with an envelope of RF modulated waveform, which can occur in the presence of gradient fields, such as, for example, a z-gradient fields as shown. Concurrent with sequence 194, in this embodiment, is initiation of a rotational magnetic field, Bᵣₒₜ, indicated as sequence 190. Following the sequence 194, a next MRI sequence 192 comprises a rapid gradient pulse followed by a slower x-gradient oscillatory excitation. During this sequence 192, a data acquisition sequence 196 is also initiated, wherein analog signals are collected (such as from sensors) and converted to digital form to enable imaging.

FIG. 19B illustrates another preferred embodiment providing a method for interleaving time intervals of a preparation phase and imaging. Here, preparation comprises three instances of sequence 194 (again, excitation at the Larmor frequency, with an envelope of RF modulated waveform, which can occur in the presence of gradient fields) with the second instance overlapping sequence 190 (a Bᵣₒₜ field interval), the preparation being used to manipulate magnetization to induce imaging contrast and/or other useful characteristics that are enhanced by the application of rotating fields, Bᵣₒₜ. The preparation phase is followed by an imaging step with conventional excitation and encoding (i.e., a Larmor excitation frequency sequence 194 followed by the gradient pulse sequence 192 concurrent with data acquisition sequence 196, the same as previously described in the embodiment illustrated by FIG. 19B, except that here the Bᵣₒₜ field is turned off during imaging. The two intervals of preparation and imaging can be repeated pair-wise as often as necessary to collect adequate intervention and imaging data.

FIG. 19C shows a further example of a timing sequence for interleaving time intervals of one or more interventions and imaging. In this embodiment, intervention comprising a Bᵣₒₜ sequence 190 is used to manipulate MNPs, e.g., to induce thermal conditioning, mix, move and/or spin the particles, and/or change some other condition of the particles or activate their function, with this intervention or activation interval followed by imaging with excitation sequence 194 (Larmor frequency, with an envelope of RF modulated waveform, which can occur in the presence of gradient fields) and encoding sequence 192 (spatial encoding with gradient fields) with data acquisition sequence 196 to monitor and/or evaluate the effects of the intervention through data processing and imaging. The two intervals (intervention and imaging) can be repeated pair-wise as often as necessary to collect adequate imaging and/or intervention data.

In further embodiments, the sequences described above in FIGS. 19A-19C can be used together in various combinations, and a multitude of additional sequences can be introduced, some of which can use additional activation magnetic and/or electric fields and additional or alternative conventional MRI sequences. The scope of the invention is not limited to the examples given above, but rather extends to include the many additional combinations of sequences that would be apparent to one skilled in the relevant art.

The computer 4 in FIG. 1 can include one or more processors and can include software modules for accepting data from monitoring sensors and/or detectors and for tracking the monitoring of multiple variables associated with the enhanced MRI operation according to the invention, such as, without limitation: temperature; MNP location and movement; magnetic or electric field amplitude, frequency, and/or direction; image data; volume indication; image contrast; T1 and T2 relaxation times; and MNP spin and flow velocities. Computer 4 can further provide feedback signals for automatically and responsively controlling the MRI apparatus components 3, 5 and 12 and/or the activation magnetic field controller 10 and in turn power supply 13 and activation magnet(s) 9 and injector 7. Computer 4 can be programmed for implementing many different sequences (duty cycles) of magnetic and/or electric field activation, such as, for example, the sequence shown in FIGS. 19A-19C.

Multiple processors, software programs and software program objects can be coupled to processing system 4 of a system 21 of the invention (see FIG. 1). Such software program objects can comprise instructions that are stored in memory and executed by the processor(s). The functions for a system of the invention can be performed by a processor executing a computer software instruction in, for example, the form of scripts, software objects, subroutines, modules, compiled programs or any other suitable program components such as downloadable applets or plug-ins. A set of instructions or programs defining system functions can be delivered to a processor in many forms. Exemplary forms can include permanently stored information on a non-writable storage media such as read-only memory devices of a computer that can be readable with an input-output attachment, information alterably stored on writable storage media such as compact disk, optical storage disks digital versatile disk, or a hard drive, information conveyed to a computer through communication media.

Conventional software is available for control over conventional MR imaging (e.g., including the timing and amplitude and phase of B1 magnetic fields and Gradients, and timing of data acquisition). According to embodiments of the invention, additional software modules are used to control the onset, duration, amplitude, frequency, phase, direction, and turn-off of MNP activation magnetic fields. For example, to capture and capitalize on change in contrast in an MRI image due to the application of a treatment intervention process by the MNPs, detection and tracking software based on amplitude or phase change in an MRI image can be used. Further, MNP activation fields can have effects on proton magnetic resonance spins that may be incorporated into and accounted for in the reconstruction of conventional MR images according to a system and methods of a preferred embodiment. The indirect effect of the activated MNP spin causing changes in MRI contrast properties is detected by software.

Preferably, a processor coupled to a system for enhanced MRI according to the invention executes a script or computer program in order to perform the corrections and/or optimization of MRI images from a subject based on the magnetic and RF signal image reconstruction. For example, the processor can be associated with the system so as to determine or analyze one or more parameters indicative of the onset or progression of a disease state in a subject, such as, for example, the progression of cardiovascular disease or a cancer. In one embodiment, the marker can be a standardized and quantifiable ferrofluid agent coupled with a biological marker that is based on the ratio of activity in an imaged region compared to background activity.

The invention also provides a method for standardizing and quantifying enhanced MR images. For example, a method of the invention can be practiced in order to standardize and quantify brain MR images. The data based on multiple sensing of RF signals and monitored EM fields resulting from one or more interventions, from diagnostic and/or therapeutic magnetic or electric fields or pulses, from MNP and/or ferrofluid motions and/or from other operations of the system according to the invention can be collected by a system of the invention that can be used to perform imaging. A method of the invention can also comprise correcting obtained images of the subject based on data that is collected from one or more imaging phantoms, such as, for example, imaging phantoms illustrated in FIGS. 12A-12D. The method of the invention can also comprise determining a suitable optimal marker and/or ferrofluid agent for a particular research, diagnostic and/or therapeutic application.

The methods disclosed herein according to the invention can be translated from the form disclosed herein to software and/or computer program form, which methods relate to the quantifiable and controllable relationships of applied magnetic fields with components of the complex magnetic susceptibility of magnetic nanoparticles (MNPs) and/or ferrofluid comprised of MNPs, of applied electric fields with scalar and/or tensor components of the complex dielectric susceptibility of dielectric nanoparticles (DNPs) and/or ferrofluid comprised of DNPs, changes in spin velocity of MNPs or DNPs, changes in magnetic forces and torques caused in MNPs by various changes in magnetic and/or electric fields (including, without limitation, rotating, oscillating, translational, uniform, AC and DC fields), thermal effects in ferrofluids caused by particle spin and changing magnetic and/or electric fields, induced changes in field states in a subject area caused by MNP or DNP spin velocity and/or by changes in MNP or DNP spin velocities, and interactive effects and/or feedbacks between applied fields and between induced fields and applied fields.

The processing can be modified according to an embodiment of the invention to provide for correcting for and/or utilizing artifacts induced upon the conventional MRI fields and signal owing to the activation magnetic and/or electric field and/or to incorporate the activation field(s) into the image reconstruction.

The mathematical expressions and relationships discussed in this application, including the numbered equations and the many physical parameters, properties, forces, processes and design criteria that they represent, are part of the disclosed method of the invention. These mathematical expressions and relationships enable quantification, analysis, deconvolution, conversion and other operations related to the method of the invention, including, without limitation, signal processing, imaging, monitoring, prediction, and control related to the method of the invention.

The ferrohydrodynmaic equations for oscillating and rotating magnetic fields described with complex amplitudes are a non-linear, complex-variable system, which can be solved by numerical simulation. Processing of these solutions for the relevant context of each embodiment of the invention can be implemented in computer software programs, modules and/or scripts. For example, FEMLAB® software is a commercial numerical finite element multiphysics package available from Comsol, Inc. (Burlington, Mass.), which can be used to perform the numerical simulations. A scripting language allows definition of FEMLAB® software models in terms of simple commands that can be incorporated into the MATLAB® computational software package (MathWorks, Natick, Mass.) scripts. The numerical solution for the full ferrohydrodynamic governing equations is approached by decoupling the system non-linear differential equations into two linear systems that are easily solved by FEMLAB® finite element models. An iterative procedure is used to numerically solve the set of governing ferrohydrodynamic equations. The algorithm starts with initial estimates for the body torque and force densities as functions of radius. Assumed forms for T_{z}(r) and F_{φ}(r) are then used to numerically solve the governing fluid mechanical equations, where T_{z} is the z directed torque density and F_{φ} is the azimuthal component of the time average force density in the ferrofluid volume, being given by

$$\begin{matrix}{F}_{φ} - 2 ζ \frac{\partial {ω}_{z}}{\partial r} + ( η + ζ ) ( \frac{{\partial }^{2} {v}_{φ}}{\partial {r}^{2}} + \frac{1}{r} \frac{\partial {v}_{φ}}{\partial r} - \frac{{v}_{φ}}{{r}^{2}} ) = 0 & ( Eq . 36 ) \\ {T}_{z} + 2 ζ ( \frac{\partial {v}_{φ}}{\partial r} + \frac{{v}_{φ}}{r} - 2 {ω}_{z} ) + {η}^{′} ( \frac{{\partial }^{2} {ω}_{z}}{\partial {r}^{2}} + \frac{1}{r} \frac{\partial {ω}_{z}}{\partial r} ) = 0 & ( Eq . 27 )\end{matrix}$$

where ζ [Ns/m²] is the vortex viscosity and from microscopic theory for dilute suspensions obeys the approximate relationship, ζ=1.5ηφ, where φ is a volume fraction of particles, η is the dynamic shear viscosity [Ns/m²], and η′ [[Ns/m²] is the shear spin viscosity. These results are subsequently input into equations known as the magnetization constitutive equations and the resulting electro-magnetic governing equations are numerically solved for the magnetic potential complex amplitude \hat{Ψ}(r). Knowledge of \hat{Ψ}(r) determines the magnetic field intensity components Ĥᵣ(r), Ĥ_{φ}(r) and magnetization \hat{M}ᵣ(r), \hat{M}_{φ}(r) and consequently a new estimate of the body torque and force densities is made. The new estimate can be used as input to the fluid mechanics governing equations to produce new estimates for the velocity and spin velocity. The algorithm allows this iterative procedure to continue until the successive estimates converge on a final value and further iterations have negligible effect on the solution.

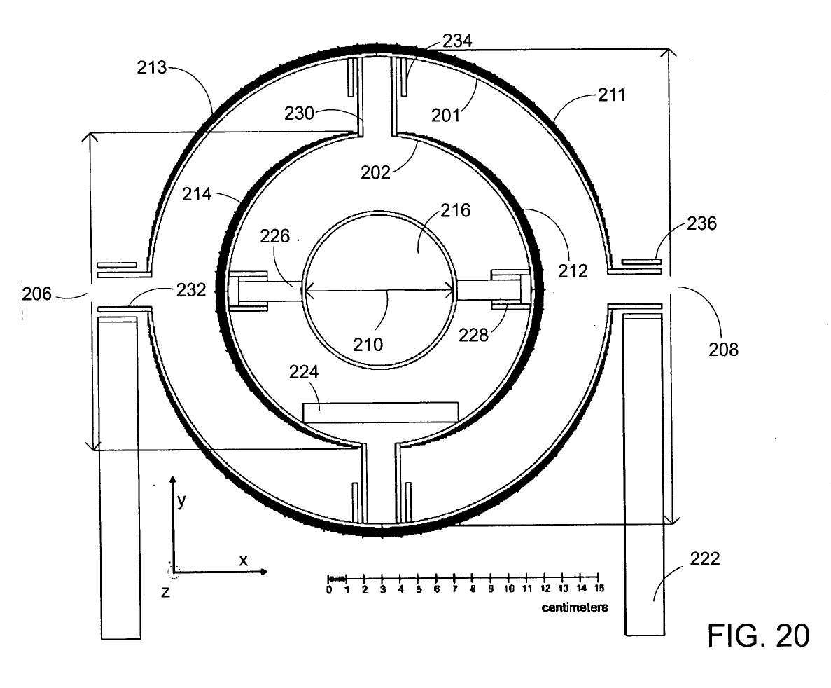

For uniform or non-uniform rotating magnetic fields, three coils can be configured orthogonally, allowing control over three components of the dipole moment in all three spatial dimensions. FIG. 20 illustrates one design, shown in cross-section, of an example of a combination of coil windings for an activation apparatus constructed in spherical orientation according to one embodiment of the invention. Although it will be appreciated that numerous other configurations and designs can be constructed according to the invention, FIG. 20 generally illustrates embodiments wherein a rotating and/or oscillating uniform magnetic field is created within a region of space, so that the field functions as an activation magnetic field created by activation magnet(s) 9 shown in FIG. 1.

Referring to FIG. 20, a double flux-sphere can be constructed to apply uniform rotating fields to a ferrofluid-containing, activation analysis chamber 216, which activation chamber 216 can be used for biomedical research and/or medical diagnosis and/or therapy, particularly when constructed in combination with an MRI apparatus according to a preferred embodiment of the invention. As depicted in FIG. 20, an outer flux sphere 201 having an outer flux sphere diameter 208 has disposed within it an inner flux sphere 202 with inner flux sphere diameter 206, where magnetic coil windings 213 and 214 are coiled around the outer and inner spheres, respectively, guided by coil-winding guide/holding flanges 211 and 212 on each of the outer and inner sphere, respectively. Activation chamber 216 having chamber diameter 210 is located inside the inner flux sphere 202. An instrument platform 224 can be attached inside the inner flux sphere. Inner flux sphere support arm(s) 230 can engage inner flux sphere support arm bearing/holder(s) 234 which can attach to the interior of the outer flux sphere 201, sample chamber support arm(s) 226 can engage sample chamber support arm bearing(s) 228 attached to the interior of the inner flux sphere 202, and outer flux sphere arm(s) 232 can engage outer flux sphere arm support bearing(s) 236 attached to main apparatus support(s) 222. The volume within the system can have a size suitable for receiving a small animal such as a mouse or a plant or a foot, hand or head of the human body. Alternatively the indicated sizes can be scaled up to receive the human body.

In FIG. 20, within the spherical region inside inner coil 202, the outer coil 201 creates a uniform magnetic field in the x direction and inner coil 202 creates a uniform magnetic field in the y direction. If outer coil 201 is excited with current I₁ Sin(ωt) and inner coil 202 is excited with current I₂ cos(ωt+φ), then the magnetic field inside inner coil 202 in general has a rotating and oscillating part dependent on the phase difference φ and relative current amplitudes and polarities of I₁ and I₂. By appropriate choice of phase angle φ and polarities and amplitudes of I₁ and I₂, the magnetic field within inner coil 202 can be made purely rotating clockwise or counter-clockwise, purely oscillating, or any combination of rotating and oscillating magnetic fields. The windings shown are 2-pole windings that create uniform magnetic fields, but multi-pole windings, such as 4-pole, 6-pole, and higher multi-pole windings can also be used to create non-uniform magnetic fields. Although FIG. 20 only illustrates two coils, a third winding can be added to create a rotational field that can be arbitrarily orientated in 3-dimensional space. The third winding can generate a field that is orthogonal to the other two field components generated by the two other orthogonal coil elements

Table 3, below, provides operating parameters, winding specifications and structure specifications for a set of embodiments of the invention, each corresponding to differing design configurations, such as, for example designs labeled herein as D1a-g, D2a-b and D3a-b. In one preferred embodiment, at least one of the specifications for designs D1a-g, among other specifications, can be utilized with the double-sphere, rotational magnetic field, activation apparatus design illustrated in FIG. 20.

TABLE 3
Operating parameters, winding specifications and structure
specifications for examples of activation apparatus according to multiple
embodiments of the invention.

| | Examples of differing embodiments | | | | | | | | | | |
|---|---|---|---|---|---|---|---|---|---|---|---|
| | D1a | D1b | D1c | D1d | D1e | D1f | D1g | D2a | D2b | D3a | D3b |
| Operating | | | | | | | | | | | |
| Parameters | | | | | | | | | | | |
| B field (Gauss) | 235 | 235 | 233 | 249 | 218 | 217 | 216 | 264 | 264 | 243 | 244 |
| Current (Amps) | 5 | 5 | 5 | 5 | 10 | 10 | 10 | 5 | 5 | 5 | 5 |
| Average radius (m) | 0.1 | 0.15 | 0.1 | 0.15 | 0.1 | 0.15 | 0.19 | 0.1 | 0.15 | 0.11 | 0.17 |
| Total turns | 1120 | 1680 | 1120 | 1792 | 520 | 760 | 980 | 1260 | 1890 | 1280 | 1920 |
| Power (Watts) | 230 | 516 | 354 | 847 | 267 | 575 | 954 | 258 | 581 | 237 | 531 |
| Winding | | | | | | | | | | | |
| Specifications | | | | | | | | | | | |
| Wire (AWG) | 18 | 18 | 18 | 18 | 15 | 15 | 15 | 18 | 18 | | |
| Wire diameter (mm) | 1.02 | 1.02 | 1.02 | 1.02 | 1.45 | 1.45 | 1.45 | 1.02 | 1.02 | | |
| # conductor layers | 7 | 7 | 7 | 7 | 5 | 5 | 5 | 7 | 7 | | |
| turns/spool | 56 | 56 | | | | | | | | | |
| winding length (m) | 559 | 1252 | | | | | | 628 | 1408 | | |
| Resistance (ohms) | 9.19 | 20.65 | 14.14 | 33.88 | 2.67 | 5.75 | 9.54 | 10.34 | 23.23 | | |
| Turns/slot | | | 8 | 8 | 2 | 2 | 2 | 63 | 63 | | |
| Structure | | | | | | | | | | | |
| specifications | | | | | | | | | | | |
| Number spools | 20 | 30 | | | | | | | | | |
| Spool height (mm) | 10 | 10 | | | | | | | | | |
| Barrel width (mm) | 20 | 20 | | | | | | 20 | 20 | | |
| Flange height (mm) | 0.5 | 0.5 | | | | | | 0.5 | 0.5 | | |
| Structure material | Del. | Del. | Del. | Del. | Del. | Del. | Del. | Del. | Del. | Del. | Del. |
| No. slots | | | 20 | 32 | 52 | 76 | 98 | 20 | 30 | | |
| Slot height (mm) | | | 2.04 | 2.04 | 3.04 | 3.04 | 3.04 | 10 | 10 | | |
| Inner Radius (cm) | | | 8 | 13 | 8 | 12.7 | 17 | | | | |
| Outer radius (cm) | | | 10 | 15 | 10 | 14.7 | 19 | | | | |

“Del.” is abbreviation for Delrin.

It will be appreciated that the specifications in Table 3 are suitable for small analysis chambers and that the system can be scaled up to dimensions for a larger chamber and activation apparatus suitable for human subjects. In such an embodiment wherein an MRI apparatus is combined with the activation apparatus, the activation chamber can be as large as the internal bore of the MRI magnet, so that a patient can be positioned inside the rotating magnetic field of the apparatus. Alternatively, the activation chamber can be smaller, designed to enclose a particular body part being treated and/or imaged, such as an arm, leg, hand, foot or brain, inter alia. Also, alternative embodiments can include cylindrical designs and modified spherical designs wherein fixed openings of various sizes can allow placement of an object or subject within a central chamber or core, or where an entrance to the chamber through the structure can be substantially opened to allow access and substantially closed during operation.

Again referring to FIG. 20, a further preferred embodiment provides for an activation apparatus in a system that provides measurement feedback of CMS tensor elements that vary with spin velocity created by the activation rotating magnetic fields. The central activation treatment and imaging chamber 216 of a preferred embodiment contains at least some amount of ferrofluid and changes in the resulting dipole field outside the chamber 216 but within the inner coil 202 can be measured by the instruments in platform 224. This enables determination of each element of the CMS tensor. In addition, torque and force sensors can be positioned in the support arms 226 of the central activation chamber 216 and/or in the bearings 228 so that the torque and force on the ferrofluid in chamber 216 can be measured as a function of magnetic field amplitude, frequency, and direction, inter alia. Ultrasound transducers can be placed within the wall of the activation chamber 216 that measure the velocity profiles from which the spin velocity can be calculated.

Another preferred embodiment of the invention combines the activation magnetic field generating system with a pre-polarized MRI (pMRI) system and method, where the periodic reduction in the Larmor frequency L₁ corresponding to a first magnetic field B₁ of an MRI system is shifted periodically to a lower Larmor frequency L₂, which may correspond to a lower amplitude of the primary MRI field. This allows an activation rotating field according to the preferred embodiment to controllably tune to a greater extent (i.e., with greater sensitivity to the activation field) the full x, y and z-directional components of the scalar or tensor CMS of the ferrofluid. In similar fashion, the activation apparatus can be combined with functional MRI (fMRI) systems and methods.

There is a direct duality of the magnetic devices to electric field devices using dielectric particles in rotating and traveling electric fields, often called dielectrophoresis. Amplitude and frequency are controlled by electrode voltages that are controlled by a power supply and electric field direction determined by design and orientation of electrodes (which can be, for example, distributed electrodes, segmented electrodes, or a multi-ribbon cable). Electric field devices can also be used together with magnetic field devices because magnetic particles generally also have dielectric and conductivity properties. Therefore, the scope of the invention includes embodiments wherein dielectrophoresis is combined with other embodiments described herein.

One advantage of the invention is the ability to steer the particles into and around the target region, which is useful for providing imaging and monitoring of the region of interest before, during, and after therapy, with and without the contrast agent present, and which can also enable the monitoring of local temperature change by detection of Larmor frequency shift of water protons.

Another advantage is that, rather than relying upon a micro or nano-electromagnet matrix of MNPs, embodiments of the invention provide for controlling the ferrofluid magnetic nanoparticle spin velocity by external control of magnetic field amplitude, frequency, phase, and direction and/or by the flow profile with vorticity which is also magnetic field controllable through the magnetic forces and torques on the ferrofluid. Magnetic torques that create MNP spin velocity occur when magnetization M̅ and magnetic field H̅ are not co-linear, typically owing to magnetization relaxation mechanisms that require a time constant for M̅ to align with H̅. This typically occurs when a rotating magnetic field is applied or when fluid flow with vorticity is imposed, such as by a pressure gradient within a channel. A force on the ferrofluid occurs when the magnetic field is non-uniform which can for example be imposed using distributed multipole windings, 4-pole and higher.

It will further be appreciated by one skilled in the art that the disclosed invention including liquid suspensions of magnetic nanoparticles can be utilized in an MRI, pMRI or fMRI setting with a variety of combinations of direct current (DC), alternating current (AC), oscillatory, rotating, and/or traveling magnetic and/or electric fields. Further, it will be appreciated that the disclosed methods and system can be utilized in combination with a wide variety of MRI diagnostic and therapeutic actions, including: thermotherapy—hyperthermia (heating) and hypothermia (cooling); enhanced MRI contrast agents; vascular agents; enhanced mixing and diffusion through fluids, tissues and membranes (absorption and/or desorption); micro/nanoelectromechanical sensing and locating disease; enhanced drug efficacy; enhanced immunoassays, separations, and cell sorting; real-time, in vivo monitoring of biochemical state; and changing of local effective viscosity, diffusion coefficient, magnetic fields due to changes in scalar or tensor CMS, or other electromagnetic and physicochemical properties; targeted electrokinetic and magnetokinetic drug delivery; and magnetic field control of MNP motions to cut, scrape, abrade or remove biological material such as tissue, plaque, gall stones, kidney stones, and/or to open blocked vessel channels such as veins, arteries, urethra, etc., inter alia. MNPs can be spherical or non-spherical shaped, such as needle-shaped, with knife-edged sharp edges or smooth edges to facilitate therapeutic applications and/or to be part of a surgical or other therapeutic procedure.

Further, it will be appreciated that the disclosed methods and system according to the invention can be utilized in combination with positional MRI (pMRI), functional MRI (fMRI), recumbent MRI (rMRI), kinetic MRI (kMRI), brain MRI (bMRI), Transcranial Magnetic Stimulation (TMS), transcranial direct current stimulation(tDCS), and repetitive TMS (rTMS), among other diagnostic and therapeutic electromagnetic technologies and methods.

In general, with respect to using ferrofluid and MNPs and altering CMS according to the invention in combination with TMS methods in the brain, the combined method can alter the distribution of the magnetic field and currents from the stimulator for improved control, imaging (particularly when coupled to MRI and EEG monitoring methods), diagnosis, and therapy, inter alia. In the context of TMS, the method of using the controllably steerable combination of various magnetic fields and/or blood-flow vorticity to alter the scalar or tensor CMS of MNPs or magnetic material in the body, such as hemoglobin, according to embodiments of the invention, can be further combined with other methods known in the art to localize and focus magnetic fields by use of an apparatus, such as, e.g., a helmet apparatus, that can be adjustably and precisely located and/or oriented with respect to the brain.

A particular advantage can be afforded by combining methods according to the invention with MRI in the context of MRI imaging adjacent to metallic objects in the body (such as, e.g., pins, plates, screws, or other orthopedic hardware, or stents, pacemakers or other implants, inter alia). Magnetizable metals, such as steel, can distort the B₀ magnetic field used in MRI because an effective magnetic dipole moment in the metal object can be induced by the initially uniform B₀ field. Additionally, although MRI can image next to non-magnetizable metals, such as, e.g., copper or aluminum, problems can arise with respect to the RF gradient field coils and readings that are used for spatial encoding, owing to induced electrical currents in the metal creating non-uniform magnetic fields. Positional MRI (pMRI) has been able to image adjacent to magnetic objects by acquiring data at low magnetic fields (about 0.2 Tesla); however, this takes much longer than when operating at higher magnetic fields. Because ferrofluid has its effective magnetic dipole moment dependent on the applied magnetic field and spin and flow velocity, a ferrofluid in proximity to an interfering metallic object can be controllably adjusted according to the invention to have a dipole moment that will cancel the magnetic dipole moment of the object, so that the B₀ field is not distorted. Improvements in imaging can thus be achieved for the case of orthopedic or other biomedical metallic objects surrounded by a ferrofluid layer whose magnetic dipole moments of metal and ferrofluid can be optimized for MRI and/or for pMRI, as well as improvements in cost and efficiency represented by shorter imaging times being required.

Combinations with functional MRI (fMRI) and ferrofluid and MNP (magnetic nanoparticle) applications according to embodiments of the invention include, inter alia, examining effects of drugs using functionalized MNPs, using MNPs with fMRI in the brain to examine brain injury, such as, e.g., from a stroke or trauma, to examine effects and conditions of brain diseases, such as, e.g., multiple sclerosis (MS), ALS, Huntington's, Parkinson's, and Alzheimer's diseases, to find evidence of disease before symptoms are evident, and/or to deliver and activate drugs to a particular region of interest. Contrast generation in fMRI is determined by proton density, T1 and T2 relaxation rates, diffusive processes of proton-spin dephasing (loss of proton phase coherence owing to tissue magnetic susceptibility variations and in-flow blood plasma protons). fMRI measures precise changes in brain activation or metabolism by the effects of local increases in blood flow and microvascular oxygenation. By utilizing blood flow vorticity and/or activation magnetic fields to alter scalar and/or tensor CMS in MNPs introduced to the blood and/or brain tissues, according to embodiments of the invention, controllable changes in imaging contrast can be caused and control over the particles can additionally be exerted, such as, e.g., inducing the MNPs to activate an interaction of a functionalized surface with tissues in a particular region of interest. According to an embodiment of the invention, MNPs can be used also in brain imaging to improve fMRI for neurosurgical planning, pain management, understanding physiological basis for neurological disorders, and physiological basis for cognitive and perceptual events, inter alia.

Alternate imaging modalities can be combined advantageously with embodiments of the invention. For example, tying a radioactive Positron Emission Tomography (PET) agent to MNPs can provide an alternate imaging modality where detection is accomplished with PET and medical intervention (e.g., thermal conditioning, mixing, etc.) can be done via controlling fields of MNPs such as described above in the context of MRI. This is advantageous because of the high sensitivity in PET-based imaging and because the magnetic fields involved are only those associated with the activation fields for the MNPs (i.e., there are no strong B0, RF, and gradient fields as in the MRI case). Thus, the PET as an imaging modality can be less affected, and the activation control of the MNPs behavior can be more independent. Along the same lines, CT, ultrasound, and/or optical modalities for detection and/or imaging can be combined with MNP-based intervention, too, such as in a scenario where the MNPs are tied to a CT-contrast agent (e.g., iodine and barium), or to an ultrasound contrast agent (e.g., SONRX® produced by Bracco Inc.), or to an optical imaging agent (e.g. Green Fluorescent Protein (GFP)).

### EQUIVALENTS

While the invention has been described in connection with specific methods and apparatus, those skilled in the art will recognize other equivalents to the specific embodiments herein. It is to be understood that the description is by way of example and not as a limitation to the scope of the invention and these equivalents are intended to be encompassed by the claims set forth below.

1. A method of magnetic resonance imaging (MRI) comprising:
preparing a ferrofluid including magnetic nanoparticles (MNPs) in a liquid carrier;
positioning the ferrofluid in a magnetic field region of a magnetic resonance imaging (MRI) system;
activating a spin velocity of one or more of the nanoparticles with a rotating magnetic field within the MRI system to alter a value of a magnetic susceptibility of the ferrofluid; and
acquiring a magnetic resonance image of the nanoparticles within a region of interest using the MRI system.

2. The method of claim 1 further comprising:
generating at least one of an oscillating magnetic, oscillating electric field, rotating magnetic field, rotating electric field, traveling magnetic field, traveling electric field, DC magnetic field, DC electric field, a magnetic field that varies with any arbitrary function of time, an electric field that varies with any arbitrary function of time, a fluid flow in a portion of the ferrofluid; and
modulating at least one of the said fields or at least one of said fluid flow to cause the nanoparticles to spin at a different velocity, to translate, or to both spin and translate.

3. The method of claim 1 further comprising moving the nanoparticles from a first position within a body to be imaged to a second position within the body.

4. The method of claim 1 further comprising using a rotating magnetic field and altering at least one of the amplitude, frequency, phase and direction of the rotating magnetic field to alter at least one of a linear velocity and a spin velocity of the MNPs.

5. The method of claim 1 further comprising:
forming a magnetic resonance (MR) image, temporally modulating the effective complex magnetic susceptibility of the ferrofluid to cause temporal modulation of signal intensity in the MR image.

6. The method of claim 5 further comprising identifying an attachment location of the MNPs.

7. The method of claim 1 further comprising using the MNPs as an MRI contrast agent.

8. The method of claim 1 further comprising preparing the MNP with a surfactant or surface coating.

9. The method of claim 8 further comprising using the surfactant to colloidally stabilize the MNPs.

10. The method of claim 1 further comprising processing image data and determining characteristics of the ferrofluid from the processed image data.

11. The method of claim 10 wherein determining the characteristics comprises a determining a temperature of the ferrofluid.

12. The method of claim 10 wherein determining the characteristic comprises determining a location of the ferrofluid within a body.

13. The method of claim 1 further comprising treating a mammalian body with the ferrofluid.

14. The method of claim 1 further comprising positioning a small animal with the ferrofluid in the magnetic field region and imaging a region of interest in the small animal.

15. The method of claim 1 further comprising positioning a plant material containing the ferrofluid in the magnetic field region and imaging the plant material.

16. The method of claim 1 further comprising applying a first magnetic field having a first orientation to a region of interest with a first coil assembly.

17. The method of claim 16 further comprising applying a second magnetic field having a second orientation to the region of interest that is orthogonal to the first orientation with a second coil assembly.

18. The method of claim 17 further comprising applying a third magnetic field having a third orientation to the region of interest.

19. The method of claim 1 further comprising actuating a spin of the NMPs at a frequency in a range about a Larmor frequency.

20. The method of claim 8 further comprising using the surfactant with at least one of selective adsorption properties and selective absorption properties for therapeutic function.

21. The method of claim 1 further comprising using a non-uniform activation magnetic field to deposit or remove adsorbed MNPs.

22. The method of claim 1 further comprising using at least one of an activation magnetic field and an activation electric field to rotate, oscillate, or move MNPs or dielectric nanoparticles to perform at least one of the steps of cutting, abrading, scraping and removing at least one of plaque, tumors, kidney stones, gall stones and other biological tissue or material.

23. The method of claim 1 further comprising using at least one of an activation magnetic field and an activation electric field wherein the at least one activation field is used to rotate, oscillate, or move MNPs or dielectric nanoparticles in order to open up blocked vessel channels for at least one of blood, urine, or other biological fluid.

24. The method of claim 1 further comprising using at least one of an activation magnetic field and an activation electric field to rotate, oscillate, or move MNPs or dielectric nanoparticles (DNPs) in order to perform micro-surgical procedures using rotation, oscillation, or other motions of MNPs, of DNPs, or of MNPs and DNPs together.

25. The method of claim 13 further comprising using the ferrofluid wherein at least a fraction of the MNPs or dielectric particles are spherical, non-spherical, or needle-like shapes and have sharp, knife-like edges or smooth edges.

26. The method of claim 1 further comprising:
combining the activation magnetic field generating system with a pre-polarized MRI (pMRI) system,
periodically reducing the Larmor frequency L₁ corresponding to a first magnetic field B₁ of the pMRI system to a lower Larmor frequency L₂ that corresponds to a lower amplitude of the primary pMRI field, and
causing an activation rotating field to controllably tune at least one of the x, y and z-directional components of the scalar or tensor CMS of the ferrofluid.

27. The method of claim 1 further comprising:
activating a magnetic field generating system of a functional MRI (fMRI) system;
periodically reducing the Larmor frequency L₁ corresponding to a first magnetic field B₁ of the fMRI system to a lower Larmor frequency L₂ that corresponds to a lower amplitude of the primary fMRI field; and
causing an activation rotating field to controllably tune at least one of the x, y and z-directional components of the scalar or tensor CMS of the ferrofluid.

28. A magnetic resonance imaging (MRI) system comprising:
a first magnetic field generating system providing a field within a spatial region in which material to be imaged is located;
an RF electromagnetic field generating and receiving system that generates magnetic resonance (MR) data in response to magnetic resonance within the material;
a data processing system that receives and processes the collected MR data, the processing system including a controller that generates a plurality of pulse parameters;
an activation magnetic field generating system that generates a rotating magnetic field; and
a ferrofluid including magnetic nanoparticles that change spin velocity in response to said rotating magnetic field, the activation magnetic field inducing a change in a value of a complex magnetic susceptibility of the ferrofluid.

29. The system of claim 28 wherein the processing system is programmed to process image data.

30. The system of claim 29 wherein the processing system is programmed to determine a characteristic of the ferrofluid from processed image data.

31. The system of claim 30 wherein the processing system determines a temperature of the ferrofluid from the processed image data.

32. The system of claim 30 wherein the processing system generates an actuating signal to actuate the activation magnetic field.

33. The system of claim 32 wherein the processing system modifies the actuating signal in response to processed image data.

34. The system of claim 32 wherein the data processing system wherein the controller actuates the first magnetic field generating system for spatial encoding.

35. The system of claim 28 wherein the activation magnetic field generating system comprises a plurality of coil assemblies generating rotating magnetic field components in different directions.

36. The system of claim 35 wherein a first coil assembly that generates a first magnetic field component and a second coil assembly that generates a second magnetic field component that is orthogonal to the first magnetic field component.

37. The system of claim 36 further comprising a third coil assembly that generates a third magnetic field component.

38. The system of claim 37 wherein the third magnetic field component is orthogonal to the first component and the second component.

39. The system of claim 28 wherein the first magnetic field generating system comprises a static magnetic field generating system and a gradient magnetic field generating system.

40. The system of claim 28 further comprising an injector that injects the ferrofluid into a body to be imaged.

41. The system of claim 28 wherein the ferrofluid comprises a plurality of MNPs that thermally treat a region of interest, the system being used to modify a temperature of biological material in the region of interest.

42. The system of claim 28 wherein the ferrofluid comprises MNPs having a diameter in a range of 5 nm to 15 nm.

43. The system of claim 28 wherein the spatial region comprises a volume adapted for a small animal or plant.

44. The system of claim 28 wherein the spatial region comprises a volume adapted for a human body.

45. The system of claim 28 wherein the activation magnetic field generating system comprises an activation magnet and activating magnetic field controller.

46. The system of claim 28 wherein the activation system actuates a response of MNPs having a characteristic frequency of about 30 MHz or higher.

47. The system of claim 28 wherein the system applies a magnetic field to decouple two atomic components in the region of interest having different spin characteristics.

48. The system of claim 47 wherein one of the two atomic components comprises C-13.

49. The system of claim 47 wherein one of the two components comprises protons.

50. The system of claim 47 wherein the activation system operates at a resonant frequency of the MNPs.

51. The system of claim 28 wherein the value of the complex magnetic susceptibility comprises a plurality of tensor values.

52. The system of claim 28 further comprises a program that adjusts a particle characteristic using the RF field and the activation magnetic field in combination.

53. The system of 52 wherein the program controls spin locking or arterial spin labeling.

54. The system of claim 28 wherein the system operates at a low magnetic field condition of less than 0.5 Tesla.

55. The system of claim 29 wherein the processing system is programmed to actuate a pulse sequence including an activation pulse component and an imaging pulse component in sequence.

56. The system of claim 55 wherein the processing system is programmed to actuate the pulse sequence comprising an RF component, a plurality of gradient field components, an acquisition period, and an activation magnetic field component having a period of spin actuation Tᵣₒₜ.

57. The system of claim 55 wherein the processing system is programmed to actuate the pulse sequence including a preparation period and a first imaging period.

58. The system of claim 55 wherein the processing system is programmed to actuate the pulse sequence comprising a rotating activation period and an imaging period.

59. The system of claim 58 wherein the processing system is programmed to actuate the pulse sequence comprising a plurality of activation and imaging periods in sequence.

60. The system of claim 29 wherein the processing system is programmed with a relaxation time selected from the group T1, T2, T1ₚ, T2ₚ and T2*.

61. A magnetic field system comprising:
a data processing system that receives and processes the collected data, the processing system including a controller that generates a plurality of pulse parameters;
an activation magnetic field generating system that generates a rotating magnetic field having a plurality in response to at least one of the pulse parameters; and
a ferrofluid including magnetic nanoparticles that change spin velocity in response to said rotating magnetic field, the rotating magnetic field inducing a change in a value of a complex magnetic susceptibility of the ferrofluid.

62. The system of claim 61 wherein the processing system is programmed to process data.

63. The system of claim 62 wherein the processing system is programmed to determine a characteristic of the ferrofluid from processed image data.

64. The system of claim 61 wherein the processing system determines a temperature of the ferrofluid from the processed image data.

65. The system of claim 61 wherein the processing system generates an actuating signal to actuate the activation magnetic field.

66. The system of claim 65 wherein the processing system modifies the actuating signal in response to processed data.

67. The system of claim 61 wherein the activation magnetic field generating system comprises a plurality of coil assemblies generating rotating magnetic field components in different directions.

68. The system of claim 67 wherein a first coil assembly that generates a first magnetic field component and a second coil assembly that generates a second magnetic field component that is orthogonal to the first magnetic field component.

69. The system of claim 68 further comprising a third coil assembly that generates a third magnetic field component.

70. The system of claim 69 wherein the third magnetic field component is orthogonal to the first component and the second component.

71. The system of claim 61 further comprising an injector that injects the ferrofluid into a body.

72. The system of claim 61 further comprising an imaging system to image the ferrofluid.

73. The system of claim 72 wherein the imaging system comprises a PET, CT, ultrasound or MRI imaging system.

74. The system of claim 61 wherein the system controls a temperature of the ferrofluid to treat a tumor within a human body.

75. The system of claim 61 wherein the system controls delivery of a drug into a human body.

76. The method of claim 1 further comprising using an activation magnetic field generating system to control the spin velocity of the nanoparticles.

77. The method of claim 76 further comprising using the activation magnetic field generating system to control a linear velocity of the nanoparticles.

78. The method of claim 76 further comprising using the activation magnetic field generating system to control an alternating magnetic field to actuate movement of the nanoparticles.
